(19) United States
(12) Patent Application Publication
(10) Pub. No.: US 2024/0324323 A1
(43) Pub. Date: Sep. 26, 2024

(54) DISPLAY DEVICE

(71) Applicant: Samsung Display Co., LTD., Yongin-si (KR)

(72) Inventors: Jong Hyun CHOI, Yongin-si (KR); Youn Joon KIM, Yongin-si (KR); Jin Ho JU, Yongin-si (KR)

(21) Appl. No.: 18/493,733

(22) Filed: Oct. 24, 2023

(30) Foreign Application Priority Data
Mar. 20, 2023 (KR) 10-2023-0035838

(51) Int. Cl. H10K 59/124; H10K 59/126

(52) U.S. Cl. CPC H10K 59/124; H10K 59/126

(57) ABSTRACT

A display device includes a substrate; an insulating layer disposed on the substrate, where an isolation groove is defined in the insulating layer, and a plurality of isolation areas is defined by the isolation groove; and a pixel circuit disposed in each of the isolation areas, where at least two portions of the isolation groove have different widths from each other.

This application claims priority to Korean Patent Application No. 10-2023-0035838, filed on Mar. 20, 2023, and all the benefits accruing therefrom under 35 U.S.C. § 119, the content of which in its entirety is herein incorporated by reference.

### BACKGROUND

### 1. Field

The present disclosure relates to a display device, and more particularly, to a display device capable of improving transmittance.

### 2. Description of the Related Art

An organic light emitting display device includes a display element, for example, an organic light emitting diode whose luminance is changed by a current.

### SUMMARY

Embodiments of the present disclosure provide a display device capable of improving transmittance.

Embodiments of the present disclosure are not limited to those mentioned above and additional objects of the present disclosure, which are not mentioned herein, will be clearly understood by those skilled in the art from the following description of the present disclosure.

According to an embodiment of the disclosure, a display device includes: a substrate; an insulating layer disposed on the substrate, where an isolation groove is defined in the insulating layer, and a plurality of isolation areas is defined by the isolation groove; and a pixel circuit disposed in each of the isolation areas, where at least two portions of the isolation groove have different widths from each other.

In an embodiment, a portion of the isolation groove may overlap a pinhole area defined by patterns of the pixel circuit, and the portion of the isolation groove overlapping the pinhole area may have a greater width than a portion of the isolation groove not overlapping the pinhole area.

In an embodiment, the portion of the isolation groove overlapping the pinhole area may have a greater depth than the portion of the isolation groove not overlapping the pinhole area.

In an embodiment, the display device may further include an upper light blocking layer disposed on the insulating layer, where an opening overlapping the pinhole area may be defined through the upper light blocking layer.

In an embodiment, the isolation groove may be further defined in a transmissive area in which a pixel including the pixel circuit is not disposed.

In an embodiment, the display device may further include an upper light blocking layer disposed on the insulating layer, where an opening overlapping the transmissive area may be defined through the upper light blocking layer.

In an embodiment, the display device may further include a line disposed in the transmissive area and connecting pixels disposed at opposing sides of the transmissive area to each other.

In an embodiment, the line may include a data line, an intermediate connection electrode, a first initialization voltage line, and a second initialization voltage line.

In an embodiment, the line may be disposed in the transmissive area not to overlap the opening of the upper light blocking layer.

In an embodiment, the line may be bent in the transmissive area to bypass the opening of the upper light blocking layer.

In an embodiment, the portion of the isolation groove overlapping the pinhole area may have a different depth from a portion of the isolation groove overlapping the transmissive area.

In an embodiment, the portion of the isolation groove overlapping the transmissive area may have a greater depth than the portion of the isolation groove overlapping the pinhole area.

In an embodiment, the pixel circuit may include a first transistor, a second transistor, a third transistor, a fourth transistor, a fifth transistor, a sixth transistor, a seventh transistor, and a capacitor.

In an embodiment, in a plan view, the pinhole area may be defined by an area surrounded by an intermediate connection electrode connecting the sixth transistor and the seventh transistor to each other, a pattern including a gate electrode of the fifth transistor, a lower light blocking layer overlapping the first transistor, and an active layer connected to the seventh transistor.

In an embodiment, in a plan view, the pinhole area may be defined by an area surrounded by a power connection electrode connected to the fifth transistor, a lower light blocking layer overlapping the first transistor, and a first initialization voltage line connected to the seventh transistor.

In an embodiment, the first transistor may include a gate electrode connected to a third node, a first electrode connected to a first node and a second electrode connected to a second node, the second transistor may include a gate electrode connected to a first gate line, a first electrode connected to a data line and a second electrode connected to the first node, the third transistor may include a gate electrode connected to a second gate line, a first electrode connected to the third node and a second electrode connected to the second node, the fourth transistor may include a gate electrode connected to a third gate line, a first electrode connected to the third node and a second electrode connected to a first initialization voltage line, the fifth transistor may include the gate electrode connected to an emission control line, a first electrode connected to a first driving voltage line and a second electrode connected to the first node, the sixth transistor may include a gate electrode connected to the emission control line, a first electrode connected to the second node and a second electrode connected to a pixel electrode, the seventh transistor may include a gate electrode connected to a fourth gate line, a first electrode connected to the pixel electrode and a second electrode connected to a second initialization voltage line, and the capacitor may include a first electrode connected to the first driving voltage line and a second electrode connected to the third node.

According to an embodiment of the disclosure, a display device may include: a substrate; an insulating layer disposed on the substrate, where an isolation groove is defined in the insulating layer, and a plurality of isolation areas is defined by the isolation groove; and a pixel circuit disposed in each of the isolation areas, where at least two portions of the isolation groove have different widths or depths from each other.

In an embodiment, a portion of the isolation groove may overlap a pinhole area defined by patterns of the pixel circuit, and the portion of the isolation groove overlapping the pinhole area may have a greater width or depth than a portion of the isolation groove not overlapping the pinhole area.

In an embodiment, the display device may further include an upper light blocking layer disposed on the insulating layer, where an opening overlapping the pinhole area may be defined through the upper light blocking layer.

In an embodiment, the isolation groove may be further disposed in a transmissive area in which a pixel including the pixel circuit is not disposed.

In an embodiment, the display device may further include an upper light blocking layer disposed on the insulating layer, where an opening overlapping the transmissive area may be defined through the upper light blocking layer.

It should be noted that the effects of the present disclosure are not limited to those described above, and other effects not mentioned will be clearly understood by those skilled in the art from the description below.

### BRIEF DESCRIPTION OF THE DRAWINGS

These and/or other features of embodiments of the invention will become apparent and more readily appreciated from the following description of the embodiments, taken in conjunction with the accompanying drawings, in which:

FIG. 1 is a perspective view of a display device according to an embodiment;

FIG. 2 is an exploded perspective view of the display device according to an embodiment;

FIG. 3 is a plan view illustrating a display panel, a display circuit board, a display driving circuit, and a touch driving circuit according to an embodiment;

FIG. 4 is a plan view illustrating a display panel, a display circuit board, a display driving circuit, and a touch driving circuit according to an embodiment;

FIG. 5 is a circuit diagram of a pixel of the display device according to an embodiment;

FIG. 6 is a circuit diagram of two pixels of the display device according to an embodiment;

FIG. 7 is a plan view of a pixel array of the display device according to an embodiment;

FIG. 8A is an enlarged view of portion A of FIG. 7;

FIG. 8B illustrates an eighth conductive layer added to FIG. 8A;

FIG. 9A is an enlarged view of portion B of FIG. 8B;

FIG. 9B illustrates the eighth conductive layer added to FIG. 9A;

FIG. 10 illustrates only a first conductive layer, a second conductive layer, and a third conductive layer among elements of FIG. 9B;

FIG. 11 illustrates only a sixth conductive layer and a seventh conductive layer among the elements of FIG. 9B;

FIG. 12 is a plan view illustrating only the second conductive layer, the third conductive layer, a fifth conductive layer, and the sixth conductive layer among the elements of FIG. 9B;

FIG. 13 is a plan view illustrating only the second through sixth conductive layers among the elements of FIG. 9B;

FIG. 14 is a plan view illustrating only the second through sixth conductive layers and first type contact holes among the elements of FIG. 9B;

FIG. 15 is a plan view illustrating only the second through seventh conductive layers and the first type contact holes among the elements of FIG. 9B;

FIG. 16 is a plan view illustrating only the second through seventh conductive layers, the first type contact holes, and second type contact holes among the elements of FIG. 9B;

FIG. 17 is a plan view illustrating only the seventh conductive layer, the eighth conductive layer, and the second type contact holes among the elements of FIG. 9b;

FIG. 18 is a plan view illustrating only the eighth conductive layer, a ninth conductive layer and third type contact holes among the elements of FIG. 9B;

FIG. 19 is a cross-sectional view of the display device according to an embodiment, taken along line I-I′ of FIG. 9B;

FIG. 20 is a cross-sectional view of the display device according to an embodiment, taken along line II-II′ of FIG. 9B;

FIG. 21 is a cross-sectional view of the display device according to an embodiment, taken along line II-II′ of FIG. 9B;

FIG. 22 is a cross-sectional view of the display device according to an embodiment, taken along line II-II′ of FIG. 9B;

FIG. 23 is a plan view of a sub-display area of the display device according to an embodiment;

FIG. 24 is a cross-sectional view of the display device according to an embodiment, taken along line III-III′ of FIG. 23;

FIG. 25 is a plan view of a sub-display area of a display device according to an embodiment;

FIG. 26 is a cross-sectional view illustrating a structure of a display element according to an embodiment;

FIGS. 27 through 30 are cross-sectional views illustrating structures of light emitting elements according to embodiments;

FIG. 31 is a cross-sectional view of an embodiment of an organic light emitting diode of FIG. 29;

FIG. 32 is a cross-sectional view of an embodiment of an organic light emitting diode of FIG. 30; and

FIG. 33 is a cross-sectional view illustrating a pixel structure of a display device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

When an element or layer is referred to as being “on” another element or layer, it includes both a case in which the element or layer is directly on another element or layer and a case in which the element or layer is on another element or layer with the other element or layer interposed therebetween. The same reference numbers indicate the same components throughout the specification. Shapes, sizes, proportions, angles, numbers, and the like, disclosed in the drawings for describing exemplary embodiments are examples, and thus, the present disclosure is not limited to those illustrated in the drawings.

It will be understood that, although the terms “first”, “second”, and the like may be used to describe various components, these components should not be limited by these terms.

These terms are only used to distinguish one component from another component.

Accordingly, a first component discussed below could be termed a second component without departing from the teachings of the present disclosure.

Each feature of the various embodiments of the present disclosure may be partially or entirely coupled or combined with each other, and is technically capable of various interlocking and driving, and each embodiment may be implemented independently of each other or may be implemented together in an association relationship.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. In the specification, “A and/or B” represents the case of A, B, or A and B. In addition, in the specification, “at least one of A and B” or “at least one selected from A and B” represents the case of A, B, or A and B. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

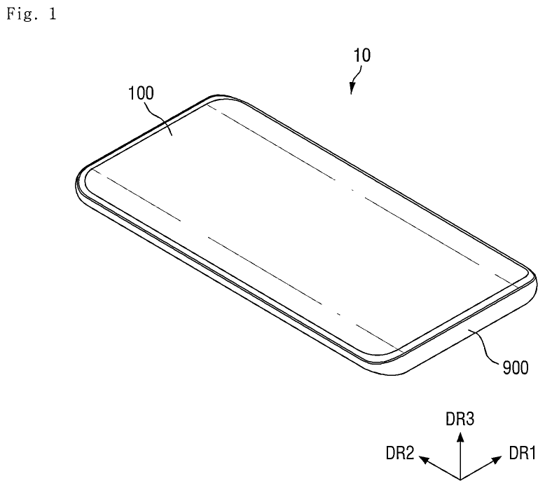

FIG. 1 is a perspective view of a display device 10 according to an embodiment.

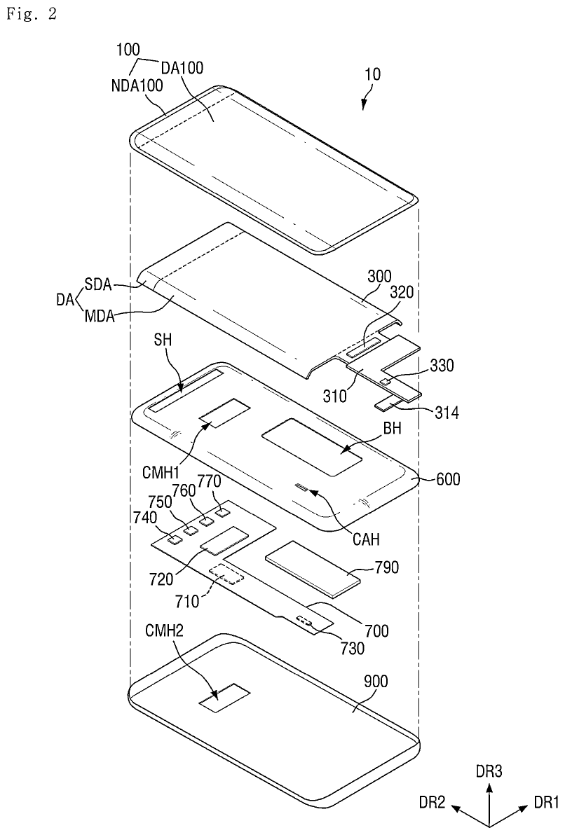

FIG. 2 is an exploded perspective view of the display device 10 according to an embodiment.

Referring to FIGS. 1 and 2, the display device 10 according to an embodiment may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). Alternatively, the display device 10 according to an embodiment may be applied as a display unit of a television, a notebook computer, a monitor, a billboard, or an Internet of things (IoT) device. Alternatively, the display device 10 according to an embodiment may be applied to wearable devices such as smart watches, watch phones, glass-like displays, and head-mounted displays (HMDs). Alternatively, the display device 10 according to an embodiment may be applied to a dashboard of a vehicle, a center fascia of a vehicle, a center information display (CID) disposed on a dashboard of a vehicle, a room mirror display replacing side mirrors of a vehicle, or a display disposed on the back of a front seat as an entertainment for a rear-seat passenger of a vehicle.

In the present specification, a first direction DR1 may be a short side direction of the display device 10, for example, a horizontal direction of the display device 10. A second direction DR2 may be a long side direction of the display device 10, for example, a vertical direction of the display device 10. A third direction DR3 may be a thickness direction of the display device 10.

The display device 10 may have a planar shape similar to a quadrangle in a plan view or when viewed in the third direction DR3. In an embodiment, for example, the display device 10 may have a planar shape similar to a quadrangle having short sides in the first direction and long sides in the second direction as illustrated in FIG. 1. Each corner where a short side extending in the first direction meets a long side extending in the second direction may be rounded with a predetermined curvature or may be right-angled. The planar shape of the display device 10 is not limited to the quadrangular shape but may also be similar to other polygonal shapes, a circular shape, or an oval shape.

The display device 10 may be substantially flat. Alternatively, the display device 10 may have a shape where two opposing side surfaces are bent. In an embodiment, for example, the display device 10 may have a shape where left and right side surfaces are bent. Alternatively, the display device 10 may be have a shape where all of the upper, lower, left and right side surfaces are bent.

The display device 10 according to an embodiment includes a cover window 100, a display panel 300, a display circuit board 310, a display driving circuit 320, a bracket 600, a main circuit board 700, optical devices 740, 750, 760 and 770, and a bottom cover 900.

The cover window 100 may be disposed on the display panel 300 to cover a front surface of the display panel 300. Thus, the cover window 100 may function to protect the front surface of the display panel 300.

The cover window 100 may include a light transmitting portion DA100 corresponding to the display panel 300 and a light blocking portion NDA100 corresponding to an area other than the display panel 300. The light blocking portion NDA100 may be opaque. Alternatively, the light blocking portion NDA100 may be a decorative layer having a pattern that may be shown to a user when an image is not displayed.

The display panel 300 may be disposed under the cover window 100. The display panel 300 may include a display area DA including a main display area MDA and a sub-display area SDA. The main display area MDA may occupy most of the display area DA.

The sub-display area SDA may be disposed on a side of the main display area MDA, for example, on an upper side of the main display area MDA as illustrated in FIG. 2, but the present disclosure is not limited thereto.

In an embodiment, the main display area MDA may not include a transmissive area that transmits light and may include only a pixel array area that includes pixels for displaying an image. In an embodiment, the sub-display area SDA may include both a transmissive area that transmits light and a pixel array area that includes pixels for displaying an image. Therefore, light transmittance of the sub-display area SDA may be higher than that of the main display area MDA.

The sub-display area SDA may overlap the optical devices 740, 750, 760 and 770 in the third direction. Accordingly, light passing through the sub-display area SDA may be incident on the optical devices 740, 750, 760 and 770. Therefore, although each of the optical devices 740, 750, 760 and 770 is covered by the display panel 300, each of the optical devices 740, 750, 760 and 770 can sense light incident from a front surface of the display device 10.

The display panel 300 may be a light emitting display panel including a light emitting element. In an embodiment, for example, the display panel 300 may be an organic light emitting display panel using an organic light emitting diode that includes an organic light emitting layer, a micro-light emitting diode display panel using a micro-light emitting diode, a quantum dot light emitting display panel using a quantum dot light emitting diode that includes a quantum dot light emitting layer, or an inorganic light emitting display panel using an inorganic light emitting element that includes an inorganic semiconductor. For convenience of description, embodiments, where the display panel 300 is an organic light emitting display panel will be mainly described below.

The display circuit board 310 and the display driving circuit 320 may be attached to a side of the display panel 300. The display circuit board 310 may be a flexible printed circuit board that can be bent, a rigid printed circuit board that is rigid and not easily bent, or a composite printed circuit board including both a rigid printed circuit board and a flexible printed circuit board.

The display driving circuit 320 may receive control signals and power supply voltages through the display circuit board 310 and generate and output signals and voltages for driving the display panel 300. The display driving circuit 320 may be formed as an integrated circuit and attached onto the display panel 300 using a chip-on-glass (COG) method, a chip-on-plastic (COP) method, or an ultrasonic method. However, the present disclosure is not limited thereto. In an alternative embodiment, for example, the display driving circuit 320 may also be attached onto the display circuit board 310.

A touch driving circuit 330 may be disposed on the display circuit board 310. The touch driving circuit 330 may be formed as an integrated circuit and attached onto an upper surface of the display circuit board 310. The touch driving circuit 330 may be electrically connected to touch electrodes of a touch sensor layer of the display panel 300 through the display circuit board 310. The touch driving circuit 330 may output touch driving signals to the touch electrodes and sense voltages charged in capacitances of the touch electrodes.

The touch driving circuit 330 may generate touch data based on a change in an electrical signal sensed by each of the touch electrodes and transmit the generated touch data to a main processor 710, and the main processor 710 may calculate touch coordinates, at which a touch has occurred, by analyzing the touch data. The touch may include a contact touch and a proximity touch. The contact touch refers to a case where an object such as a human finger or a pen directly contacts the cover window 100 disposed on the touch electrode layer. The proximity touch refers to a case where an object such as a human finger or a pen is positioned (e.g., hovers) above the cover window 100 in proximity to the cover window 100.

In an embodiment, a power supply unit for supplying display driving voltages for driving the display driving circuit 320 may be additionally disposed on the display circuit board 310.

The bracket 600 may be disposed under the display panel 300. The bracket 600 may include plastic, metal, or both plastic and metal. The bracket 600 may be provided with a first camera hole CMH1 into which a first camera sensor 720 is inserted, a battery hole BH in which a battery is disposed, a cable hole CAH through which a cable 314 connected to the display circuit board 310 passes, and a light transmission hole SH in which the optical devices 740, 750, 760 and 770 are disposed. Alternatively, the bracket 600 may be formed not to overlap the sub-display area SDA of the display panel 300 instead of including the light transmission hole SH.

The main circuit board 700 and a battery 790 may be disposed under the bracket 600. The main circuit board 700 may be a printed circuit board or a flexible printed circuit board.

The main circuit board 700 may include the main processor 710, the first camera sensor 720, a main connector 730, and the optical devices 740, 750, 760 and 770. The optical devices 740, 750, 760 and 770 may include a proximity sensor 740, an illuminance sensor 750, an iris sensor 760, and a second camera sensor 770.

The first camera sensor 720 may be disposed on both an upper surface and a lower surface of the main circuit board 700, the main processor 710 may be disposed on the upper surface of the main circuit board 700, and the main connector 730 may be disposed on the lower surface of the main circuit board 700. The proximity sensor 740, the illuminance sensor 750, the iris sensor 760, and the second camera sensor 770 may be disposed on the upper surface of the main circuit board 700.

The main processor 710 may control all the functions of the display device 10. In an embodiment, for example, the main processor 710 may output digital video data to the display driving circuit 320 through the display circuit board 310 so that the display panel 300 can display an image. In addition, the main processor 710 may receive touch data from the touch driving circuit 330, determine coordinates of a user's touch, and then execute an application indicated by an icon displayed at the coordinates of the user's touch. In addition, the main processor 710 may convert first image data received from the first camera sensor 720 into digital video data and output the digital video data to the display driving circuit 320 through the display circuit board 310. Thus, an image captured by the first camera sensor 720 can be displayed on the display panel 300. In addition, the main processor 710 may control the display device 10 based on sensor signals received from the proximity sensor 740, the illuminance sensor 750, the iris sensor 760, and the second camera sensor 770.

The main processor 710 may determine whether an object is located close to the front surface of the display device 10 based on a proximity sensor signal received from the proximity sensor 740. When an object is located close to the front surface of the display device 10 in a call mode in which a user talks to the other party using the display device 10, the main processor 710 may not execute an application indicated by an icon displayed at touch coordinates even if the user performs a touch action.

The main processor 710 may determine the brightness of the front surface of the display device 10 based on an illuminance sensor signal received from the illuminance sensor 750. The main processor 710 may adjust the luminance of an image displayed on the display panel 300 based on the brightness of the front surface of the display device 10.

The main processor 710 may determine whether an iris image of a user is identical to an iris image pre-stored in a memory based on an iris sensor signal received from the iris sensor 760. When the iris image of the user is identical to the iris image pre-stored in the memory, the main processor 710 may unlock the display device 10 and display a home screen on the display panel 300.

The main processor 710 may generate digital video data according to second image data received from the second camera sensor 770. The main processor 710 may output the digital video data to the display driving circuit 320 through the display circuit board 310. Thus, an image captured by the second camera sensor 770 can be displayed on the display panel 300.

The first camera sensor 720 processes an image frame such as a still image or a moving image obtained by an image sensor and outputs the processed image frame to the main processor 710. The first camera sensor 720 may be a complementary metal-oxide-semiconductor (CMOS) image sensor or a charge-coupled device (CCD) sensor. The first camera sensor 720 may be exposed on a lower surface of the bottom cover 900 by a second camera hole CMH2. Thus, the first camera sensor 720 can photograph an object or background disposed under the display device 10.

The cable 314 may be connected to the main connector 730 by passing through the cable hole CAH of the bracket 600. Therefore, the main circuit board 700 may be electrically connected to the display circuit board 310.

The proximity sensor 740 is a sensor for detecting whether an object is located close to the front surface of the display device 10. The proximity sensor 740 may include a light source which outputs light and a light reception unit which receives light reflected by an object. The proximity sensor 740 may determine whether there is an object located close to the front surface of the display device 10 based on the amount of light reflected by the object. Since the proximity sensor 740 is disposed to overlap the light transmission hole SH, the sub-display area SDA of the display panel 300 and the light transmitting portion DA100 of the cover window 100 in the third direction, the proximity sensor 740 may generate a proximity sensor signal according to whether there is an object located close to the front surface of the display device 10 and output the proximity sensor signal to the main processor 710.

The illuminance sensor 750 is a sensor for detecting the brightness of the front surface of the display device 10. The illuminance sensor 750 may include a resistor whose resistance value varies according to the brightness of incident light. The illuminance sensor 750 may determine the brightness of the front surface of the display device 10 based on the resistance value of the resistor. Since the illuminance sensor 750 is disposed to overlap the light transmission hole SH, the sub-display area SDA of the display panel 300 and the light transmitting portion DA100 of the cover window 100 in the third direction, the illuminance sensor 750 may generate an illuminance sensor signal according to the brightness of the front surface of the display device 10 and output the illuminance sensor signal to the main processor 710.

The iris sensor 760 is a sensor for detecting whether a photographed image of a user's iris is identical to an iris image pre-stored in the memory. Since the iris sensor 760 is disposed to overlap the light transmission hole SH, the sub-display area SDA of the display panel 300 and the light transmitting portion DA100 of the cover window 100 in the third direction, the iris sensor 760 may photograph the user's iris disposed above the display device 10. The iris sensor 760 may generate an iris sensor signal according to whether the iris image of the user is identical to the iris image pre-stored in the memory and output the iris sensor signal to the main processor 710.

The second camera sensor 770 processes an image frame such as a still image or a moving image obtained by an image sensor and outputs the processed image frame to the main processor 710. The second camera sensor 770 may be a CMOS image sensor or a CCD sensor. The number of pixels of the second camera sensor 770 may be smaller than the number of pixels of the first camera sensor 720, and a size of the second camera sensor 770 may be smaller than a size of the first camera sensor 720. Since the second camera sensor 770 is disposed to overlap the light transmission hole SH, the sub-display area SDA of the display panel 300 and a second light transmitting portion SDA100 of the cover window 100 in the third direction, the second camera sensor 770 may photograph an object or background disposed above the display device 10.

The battery 790 may be disposed not to overlap the main circuit board 700 in the third direction. The battery 790 may overlap the battery hole BH of the bracket 600.

In addition, the main circuit board 700 may further include a mobile communication module capable of transmitting and receiving wireless signals to and from at least one of a base station, an external terminal, and a server over a mobile communication network. The wireless signals may include voice signals, video call signals, or various types of data according to transmission/reception of text/multimedia messages.

The bottom cover 900 may be disposed under the main circuit board 700 and the battery 790. The bottom cover 900 may be fastened and fixed to the bracket 600. The bottom cover 900 may form the bottom exterior of the display device 10. The bottom cover 900 may include plastic, metal, or both plastic and metal.

The second camera hole CMH2 exposing a lower surface of the first camera sensor 720 may be provided (i.e., defined or formed) in the bottom cover 900. The position of the first camera sensor 720 and the positions of the first and second camera holes CMH1 and CMH2 corresponding to the first camera sensor 720 are not limited to the embodiment illustrated in FIG. 2.

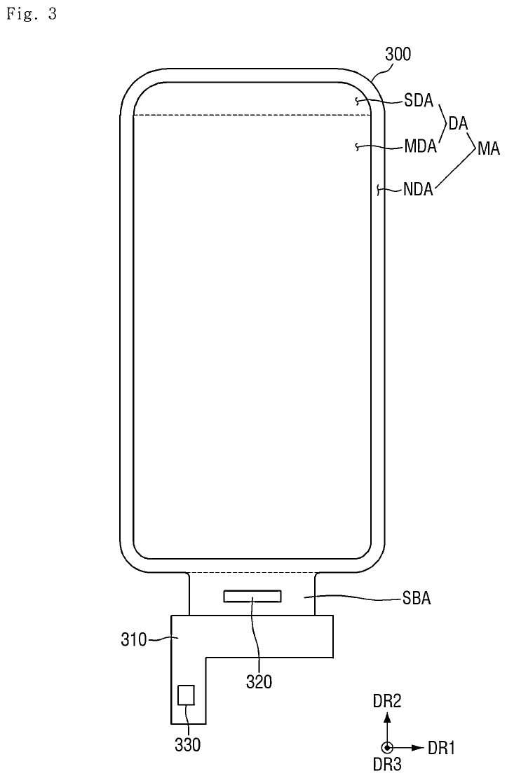

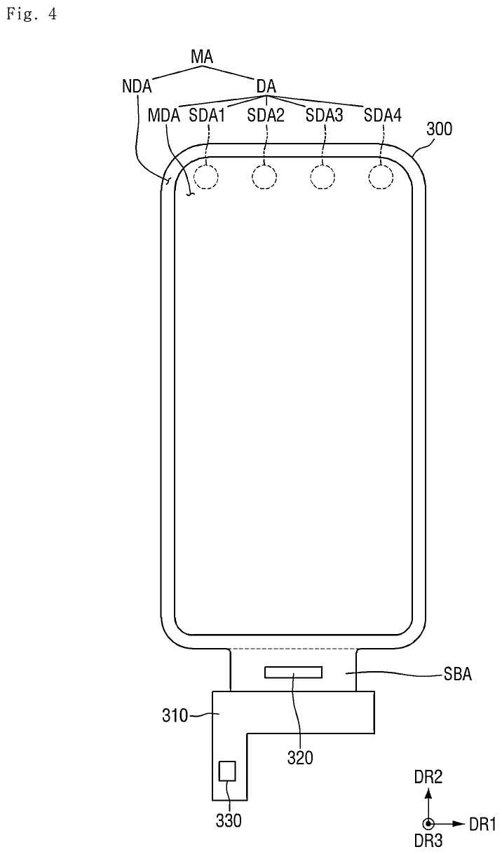

FIG. 3 is a plan view illustrating a display panel 300, a display circuit board 310, a display driving circuit 320, and a touch driving circuit 330 according to an embodiment. FIG. 4 is a plan view illustrating a display panel 300, a display circuit board 310, a display driving circuit 320, and a touch driving circuit 330 according to an embodiment.

Referring to FIG. 3, an embodiment of the display panel 300 may be a rigid display panel that is hard and not easily bent or a flexible display panel that is flexible and can be easily bent, folded or rolled. In an embodiment, for example, the display panel 300 may be a foldable display panel that can be folded and unfolded, a curved display panel whose display surface is curved, a bended display panel whose areas other than a display surface are bent, a rollable display panel that can be rolled or unrolled, or a stretchable display panel that can be stretched.

In an embodiment, the display panel 300 may be a transparent display panel that is implemented to be transparent so that an object or background disposed on a lower surface of the display panel 300 can be seen from the front of the display panel 300. In addition, the display panel 300 may be a reflective display panel that can reflect an object or background in front of the display panel 300.

The display panel 300 may include a main area MA and a sub area SBA protruding or extending from a side of the main area MA. The main area MA may include a display area DA which displays an image and a non-display area NDA which is disposed around the display area DA. The display area DA may occupy most of the main area MA. The display area DA may be disposed in the center of the main area MA. The non-display area NDA may be an area outside the display area DA. The non-display area NDA may be defined as an edge area of the display panel 300.

The display area DA may include a main display area MDA and a sub-display area SDA. The main display area MDA may occupy most of the display area DA.

In an embodiment, the main display area MDA may not include a transmissive area that transmits light and may include only a pixel array area that includes pixels for displaying an image. In such an embodiment, the sub-display area SDA may include both a transmissive area that transmits light and a pixel array area that includes pixels for displaying an image. Therefore, light transmittance of the sub-display area SDA may be higher than that of the main display area MDA.

The sub-display area SDA may overlap the optical devices 740, 750, 760 and 770 in the third direction. Accordingly, light passing through the sub-display area SDA may be incident on the optical devices 740, 750, 760 and 770. Therefore, although each of the optical devices 740, 750, 760 and 770 is disposed to overlap the display panel 300, each of the optical devices 740, 750, 760 and 770 can sense light incident from the front surface of the display device 10.

The sub-display area SDA may be disposed on a side of the main display area MDA, for example, on an upper side of the main display area MDA as illustrated in FIG. 3. However, the present disclosure is not limited thereto. In an alternative embodiment, for example, the sub-display area SDA may be disposed on a left side, a right side, or a lower side of the main display area MDA. Alternatively, the sub-display area SDA may be disposed adjacent to the center of the main display area MDA and surrounded by the main display area MDA. Alternatively, the sub-display area SDA may be disposed adjacent to a corner of the display panel 300.

Alternatively, the display area DA may include a plurality of sub-display areas SDA1 through SDA4 as illustrated in FIG. 4. The sub-display areas SDA1 through SDA4 may be spaced apart from each other. Each of the sub-display areas SDA1 through SDA4 may be surrounded by the main display area MDA.

A first sub-display area SDA1 may overlap the proximity sensor 740 in the third direction. Therefore, even though the proximity sensor 740 is disposed to overlap the display panel 300, the proximity sensor 740 can sense light incident from the front surface of the display device 10 through the first sub-display area SDA1.

A second sub-display area SDA2 may overlap the illuminance sensor 750 in the third direction. Therefore, even though the illuminance sensor 750 is disposed to overlap the display panel 300, the illuminance sensor 750 can sense light incident from the front surface of the display device 10 through the second sub-display area SDA2.

A third sub-display area SDA3 may overlap the iris sensor 760 in the third direction. Therefore, even though the iris sensor 760 is disposed to overlap the display panel 300, the iris sensor 760 can sense light incident from the front surface of the display device 10 through the third sub-display area SDA3.

A fourth sub-display area SDA4 may overlap the second camera sensor 770 in the third direction. Therefore, even though the second camera sensor 770 is disposed to overlap the display panel 300, the second camera sensor 770 can sense light incident from the front surface of the display device 10 through the fourth sub-display area SDA4.

The display device DA may include four sub-display areas SDA1 through SDA4 as illustrated in FIG. 4, but the present disclosure is not limited thereto. The number of sub-display areas SDA1 through SDA4 may depend on the number of optical devices 740, 750, 760 and 770. The sub-display areas SDA1 through SDA4 may be disposed to correspond one-to-one to the optical devices 740, 750, 760 and 770.

Each of the sub-display areas SDA1 through SDA4 may be circular as illustrated in FIG. 4, but the present disclosure is not limited thereto. In an alternative embodiment, for example, each of the sub-display areas SDA1 through SDA4 may also be polygonal or oval. In an embodiment, the sub-display areas SDA1 through SDA4 may have a same size as each other as illustrated in FIG. 4, but the present disclosure is not limited thereto. Alternatively, the sub-display areas SDA1 through SDA4 may also have different sizes from each other.

The sub area SBA may protrude from a side of the main area MA in the second direction. In an embodiment, as illustrated in FIG. 3, a length of the sub area SBA in the first direction DR1 may be smaller than a length of the main area MA in the first direction, and a length of the sub area SBA in the second direction may be smaller than a length of the main area MA in the second direction, but the present disclosure is not limited thereto.

In an embodiment, the sub area SBA may be bent and disposed under the display panel 300. In such an embodiment, the sub area SBA may be disposed to overlap the main area MA in the third direction.

In an embodiment, the sub area SBA of the display panel 300 may be bent and disposed under the display panel 300 as illustrated in FIG. 2. In such an embodiment, the sub area SBA of the display panel 300 may be disposed to overlap the main area MA of the display panel 300 in the third direction.

The display circuit board 310 and the display driving circuit 320 may be attached to the sub area SBA of the display panel 300. The display circuit board 310 may be attached onto pads of the sub area SBA of the display panel 300 by using a low-resistance high-reliability material such as an anisotropic conductive film or a self-assembly anisotropic conductive paste (SAP). The touch driving circuit 330 may be disposed on the display circuit board 310.

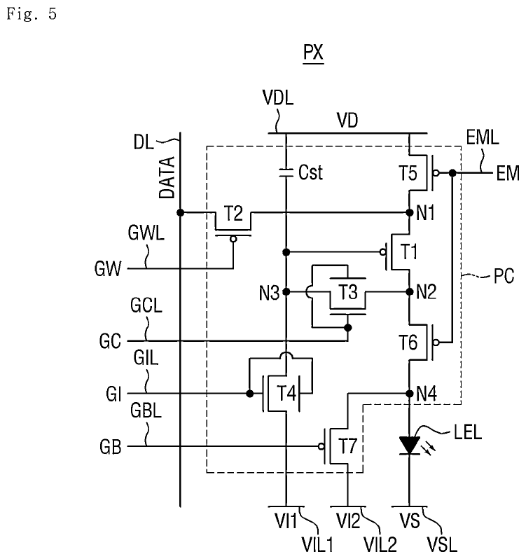

FIG. 5 is a circuit diagram of a pixel PX of the display device 10 according to an embodiment.

In an embodiment, the pixel PX may be connected to a first gate line GWL, a second gate line GCL, a third gate line GIL, a fourth gate line GBL, an emission control line EML, a data line DL, a first driving voltage line VDL, a second driving voltage line VSL, a first initialization voltage line VIL1, and a second initialization voltage line VIL2.

The pixel PX may include a pixel circuit PC and a light emitting element LEL. The pixel circuit PC may include a first transistor T1, a second transistor T2, a third transistor T3, a fourth transistor T4, a fifth transistor T5, a sixth transistor T6, a seventh transistor T7, and a capacitor Cst.

The first transistor T1 may include a gate electrode, a source electrode, and a drain electrode. The first transistor T1 may control a source-drain current (hereinafter, referred to as a driving current) based on a data voltage applied to the gate electrode. The driving current flowing through a channel region of the first transistor T1 may be proportional to the square of a difference between a voltage between the source electrode and the gate electrode of the first transistor T1 and a threshold voltage (i.e., Isd=k×(Vsg−Vth)², where Isd denotes a driving current, k denotes a proportional coefficient determined by the structure and physical characteristics of the first transistor T1, Vsg denotes a source-gate voltage of the first transistor T1, and Vth denotes a threshold voltage of the first transistor T1).

The light emitting element LEL may receive the driving current (Isd) and emit light. The amount of light emitted from the light emitting element LEL or the luminance of the light emitting element LEL may be proportional to the magnitude of the driving current (Isd).

The light emitting element LEL may be an organic light emitting diode including a first electrode, a second electrode, and an organic light emitting layer disposed between the first electrode and the second electrode. In an alternative embodiment, for example, the light emitting element LEL may be an inorganic light emitting element including a first electrode, a second electrode, and an inorganic semiconductor disposed between the first electrode and the second electrode. In an alternative embodiment, for example, the light emitting element LEL may be a quantum dot light emitting element including a first electrode, a second electrode, and a quantum dot light emitting layer disposed between the first electrode and the second electrode. In an alternative embodiment, for example, the light emitting element LEL may be a micro-light emitting diode.

The first electrode of the light emitting element LEL may be electrically connected to a fourth node N4. The first electrode of the light emitting element LEL may be connected to a drain electrode of the sixth transistor T6 and a source electrode of the seventh transistor T7 through the fourth node N4. The second electrode of the light emitting element LEL may be connected to the second driving voltage line VSL. The second electrode of the light emitting element LEL may receive a second driving voltage (e.g., a low potential voltage) from the second driving voltage line VSL.

The second transistor T2 may be turned on by a first gate signal GW of the first gate line GWL to electrically connect the data line DL and a first node N1 which is the source electrode of the first transistor T1. The second transistor T2 may be turned on based on the first gate signal GW to supply a data voltage to the first node N1. The second transistor T2 may include a gate electrode electrically connected to the first gate line GWL, a source electrode electrically connected to the data line DL, and a drain electrode electrically connected to the first node N1.

The third transistor T3 may be turned on by a second gate signal GC of the second gate line GCL to electrically connect a second node N2 which is the drain electrode of the first transistor T1 and a third node N3 which is the gate electrode of the first transistor T1. The third transistor T3 may be connected in series between the second node N2 and the third node N3. The third transistor T3 may include a gate electrode electrically connected to the second gate line GCL, a source electrode electrically connected to the third node N3, and a drain electrode electrically connected to the second node N2. The third transistor T3 may include the gate electrode and a counter gate electrode facing each other with an active layer interposed between them. In other words, the third transistor T3 may be a double-gate transistor.

The fourth transistor T4 may be turned on by a third gate signal GI of the third gate line GIL to electrically connect the third node N3 which is the gate electrode of the first transistor T1 and the first initialization voltage line VIL1. The fourth transistor T4 may be connected in series between the third node N3 and the first initialization voltage line VIL1. The fourth transistor T4 may include a gate electrode electrically connected to the third gate line GIL, a source electrode electrically connected to the third node N3, and a drain electrode electrically connected to the first initialization voltage line VIL1. The fourth transistor T4 may include the gate electrode and a counter gate electrode facing each other with an active layer interposed between them. In other words, the fourth transistor T4 may be a double-gate transistor.

The fifth transistor T5 may be turned on by an emission control signal EM of the emission control line EML to electrically connect the first driving voltage line VDL and the first node N1 which is the source electrode of the first transistor T1. The fifth transistor T5 may include a gate electrode electrically connected to the emission control line EML, a source electrode electrically connected to the first driving voltage line VDL, and a drain electrode electrically connected to the first node N1.

The sixth transistor T6 may be turned on by the emission control signal EM of the emission control line EML to electrically connect the second node N2 which is the drain electrode of the first transistor T1 and the fourth node N4 which is the first electrode of the light emitting element LEL. The sixth transistor T6 may include a gate electrode electrically connected to the emission control line EML, a source electrode electrically connected to the second node N2, and the drain electrode electrically connected to the fourth node N4.

When all of the fifth transistor T5, the first transistor T1, and the sixth transistor T6 are turned on, the driving current may be supplied to the light emitting element LEL.

The seventh transistor T7 may be turned on by a fourth gate signal GB of the fourth gate line GBL to electrically connect the fourth node N4 which is the first electrode of the light emitting element LEL and the second initialization voltage line. VIL2. The seventh transistor T7 may be turned on based on the fourth gate signal GB to discharge the first electrode of the light emitting element LEL to a second initialization voltage. The seventh transistor T7 may include a gate electrode electrically connected to the fourth gate line GBL, the source electrode electrically connected to the fourth node N4, and a drain electrode electrically connected to the second initialization voltage line VIL2.

Each of the first transistor T1, the second transistor T2, the fifth transistor T5, the sixth transistor T6, and the seventh transistor T7 among the first through seventh transistors described above may include a silicon-based active layer. In an embodiment, for example, each of the first transistor T1, the second transistor T2, the fifth transistor T5, the sixth transistor T6, and the seventh transistor T7 may include an active layer made of low-temperature polycrystalline silicon (LTPS). The active layer made of low-temperature polycrystalline silicon may have high electron mobility and excellent turn-on characteristics. Therefore, the display device 10 including the transistors having excellent turn-on characteristics can stably and efficiently drive a plurality of pixels PX.

In addition, each of the first transistor T1, the second transistor T2, the fifth transistor T5, the sixth transistor T6, and the seventh transistor T7 described above may correspond to a p-type transistor. In an embodiment, for example, each of the first transistor T1, the second transistor T2, the fifth transistor T5, the sixth transistor T6, and the seventh transistor T7 may output a current flowing to the source electrode to the drain electrode based on a gate-low voltage applied to the gate electrode.

Each of the third transistor T3 and the fourth transistor T4 may include an oxide-based active layer. A transistor including an oxide-based active layer may have a coplanar structure in which a gate electrode is disposed on the active layer. The transistor including the oxide-based active layer may correspond to an n-type transistor and may output a current flowing to a drain electrode to a source electrode based on a gate-high voltage applied to the gate electrode.

The capacitor Cst may be electrically connected between the third node N3 which is the gate electrode of the first transistor T1 and the first driving voltage line VDL. In an embodiment, for example, a first electrode of the capacitor Cst may be electrically connected to the third node N3, and a second electrode of the capacitor Cst may be electrically connected to the first driving voltage line VDL. Accordingly, a potential difference between the first driving voltage line VDL and the gate electrode of the first transistor T1 may be maintained.

The display panel 300 of the display device 10 may include a plurality of pixels arranged along p rows (p is a natural number) and q columns (q is a natural number), and each pixel can be expressed as an equivalent circuit as in the embodiment illustrated in FIG. 5.

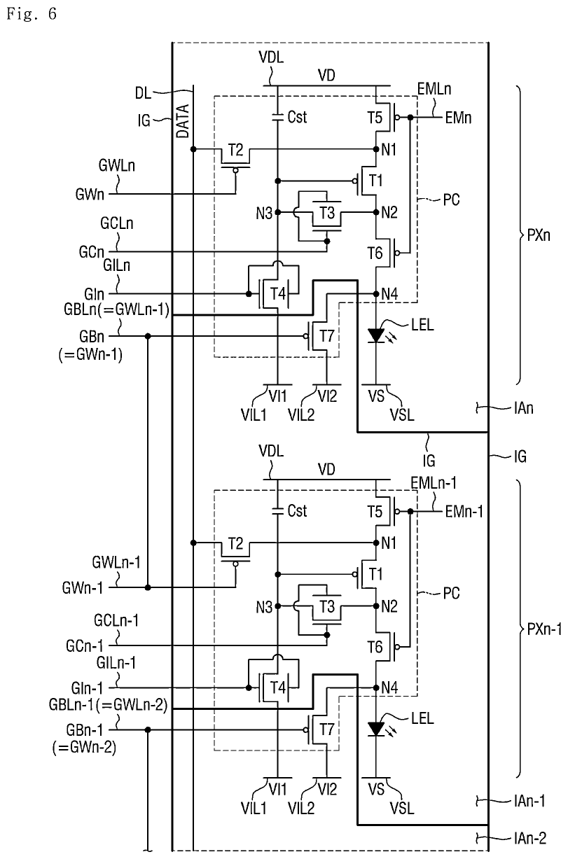

FIG. 6 is a circuit diagram of two pixels of the display device 10 according to an embodiment.

Each of an n^{th} pixel PXn and an (n−1)^{th} pixel PXn−1 may include first through seventh transistors T1 through T7 and a capacitor Cst as illustrated in FIG. 5 described above. Here, n may be a natural number greater than 1.

The n^{th} pixel PXn and the (n−1)^{th} pixel PXn−1 may be connected to the same data line DL.

The (n−1)^{th} pixel PXn−1 may be a pixel that is driven earlier in time than the n^{th} pixel PXn. In an embodiment, for example, the (n−1)^{th} pixel PXn−1 may be driven in an earlier horizontal period than the n^{th} pixel PXn. In such an embodiment, the (n−1)^{th} pixel PXn−1 may receive gate signals and an emission control signal earlier than those transmitted to the n^{th} pixel PXn by one horizontal period. In an embodiment, for example, the n^{th} pixel PXn may receive an n^{th} first gate signal GWn, an n^{th} second gate signal GCn, an n^{th} third gate signal GIn, an n^{th} fourth gate signal GBn, and an n^{th} emission control signal EMn. In addition, the (n−1)^{th} pixel PXn−1 may receive an (n−1)^{th} first gate signal GWn−1, an (n−1)^{th} second gate signal GCn−1, an (n−1)^{th} third gate signal GIn−1, an (n−1)^{th} fourth gate signal GBn−1, and an (n−1)^{th} emission control signal EMn−1.

The n^{th} pixel PXn may be connected to an n^{th} first gate line GWLn, an n^{th} second gate line GCLn, an n^{th} third gate line GILn, an n^{th} fourth gate line GBLn, and an n^{th} emission control line EMLn. In addition, the (n−1)^{th} pixel PXn−1 may be connected to an (n−1)^{th} first gate line GWLn−1, an (n−1)^{th} second gate line GCLn−1, an (n−1)^{th} third gate line GILn−1, an (n−1)^{th} fourth gate line GBLn−1, and an (n−1)^{th} emission control line EMLn−1.

At least one transistor of the n^{th} pixel PXn, for example, the seventh transistor T7 may receive a first gate signal of the (n−1)^{th} pixel PXn−1, which is a previous pixel, as the fourth gate signal GBn. In an embodiment, the seventh transistor T7 of the n^{th} pixel PXn may be connected to the first gate line GWLn−1 of the (n−1)^{th} pixel PXn−1. Therefore, the seventh transistor T7 of the n^{th} pixel PXn may receive the (n−1)^{th} first gate signal GWn−1 of the (n−1)^{th} pixel PXn−1.

A pixel circuit PC of each of the pixels PXn and PXn−1 may be disposed in an isolation area IAn or IAn−1 surrounded and defined by an isolation groove IG. Here, at least one of the elements of each of the pixels PXn and PXn−1 may be disposed in another isolation area. In an embodiment, for example, the seventh transistor T7 of the n^{th} pixel PXn may be disposed in an (n−1)^{th} isolation area IAn−1.

The pixel circuits PC of the pixels PXn and PXn−1 may have a same configuration as each other.

A plurality of different pixels may also be disposed in one isolation area. In an embodiment, for example, a plurality of pixel circuits PC connected to different light emitting elements may be disposed in one isolation area.

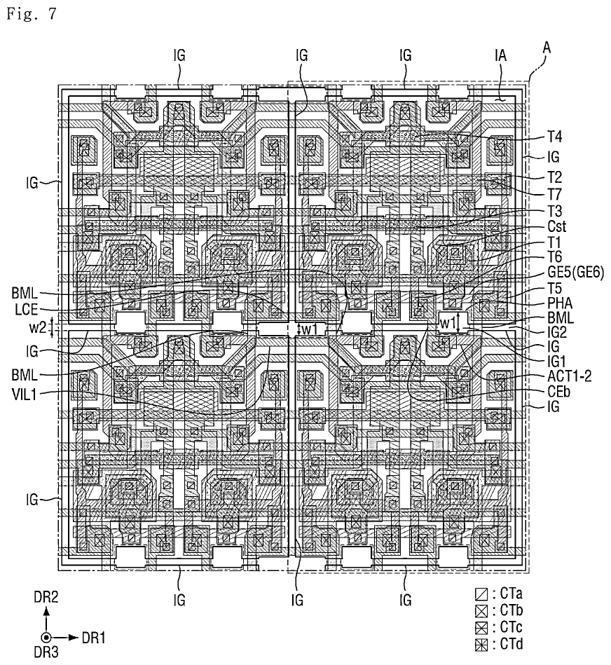

FIG. 7 is a plan view of a pixel array of the display device 10 according to an embodiment.

The display device 10 according to an embodiment of the present disclosure may include an isolation groove IG defining four isolation areas IA as illustrated in FIG. 7.

Two pixels may be disposed in one isolation area IA. In an embodiment, for example, pixel circuits of two pixels may be disposed in one isolation area IA. One pixel circuit may include first through seventh transistors T1 through T7 and a capacitor Cst. The first through seventh transistors T1 through T7 and the capacitor Cst of FIG. 7 may correspond to the first through seventh transistors T1 through T7 and the capacitor Cst of FIG. 6, respectively.

As illustrated in FIG. 7, the isolation groove IG may have a mesh shape in which portions extending in a first direction DR1 and portions extending in a second direction DR2 are connected to each other.

At least a portion of the isolation groove IG extending in the first direction DR1 may have a different width from other portions. Here, the width may mean, for example, a size or length in the second direction DR2 or a direction perpendicular to the extending direction DR1. In an embodiment, for example, the width of the isolation groove IG may mean, for example, a size or length in an extending direction (or longitudinal direction) of a data line DL.

In an embodiment, for example, portions of the isolation groove IG which are disposed in pinhole areas PHA of the pixel circuits may have a different width from other portions of the isolation groove IG. In an embodiment, for example, a width of portions of the isolation groove IG which overlap the pinhole areas PHA may be greater than a width of other portions of the isolation groove IG. In other words, the isolation groove IG may have a greater width in the pinhole areas PHA. Specifically, when an area excluding the pinhole areas PHA (or an area other than the pinhole areas PHA) is defined as a non-pinhole area, the isolation groove IG may have a greater width in the pinhole areas PHA than in the non-pinhole area. In an embodiment, for example, a width w1 (e.g., a size in the second direction) of the isolation groove IG in the pinhole areas PHA may be greater than a width w2 (e.g., a size in the second direction) of the isolation groove IG in the non-pinhole area. In an embodiment, portions of the isolation groove IG which are disposed in the pinhole areas PHA may be defined as first isolation grooves IG1, and portions of the isolation groove which are disposed in the non-pinhole area may be defined as a second isolation groove IG2. In such an embodiment, a width w1 of the first isolation grooves IG1 may be greater than a width w1 of the second isolation groove IG2.

In an embodiment, for example, the pinhole areas PHA may be defined by patterns of pixels (or pixel circuits PC of the pixels). In other words, areas larger than a preset reference value among areas surrounded by patterns constituting pixels may be defined as the pinhole areas PHA. The light transmittance of the pixels may be improved by the pinhole areas PHA. Accordingly, the light transmittance of the sub-display area SDA described above may be improved. Here, since the isolation groove IG has a greater width in the pinhole areas PHA than in other areas, the light transmittance of the pinhole areas PHA may be further improved. In an embodiment, for example, since the isolation groove IG is defined or formed through an insulating layer, the insulating layer may be removed relatively more in the pinhole areas PHA where the isolation groove IG is disposed than in other areas. Therefore, the light transmittance of the pinhole areas PHA may be further improved. Accordingly, the amount of light incident on the optical devices 740, 750, 760 and 770 disposed in the sub-display area SDA or the amount of light emitted from the optical devices 740, 750, 760 and 770 may increase, thereby improving the accuracy of the optical devices 740, 750, 760 and 770.

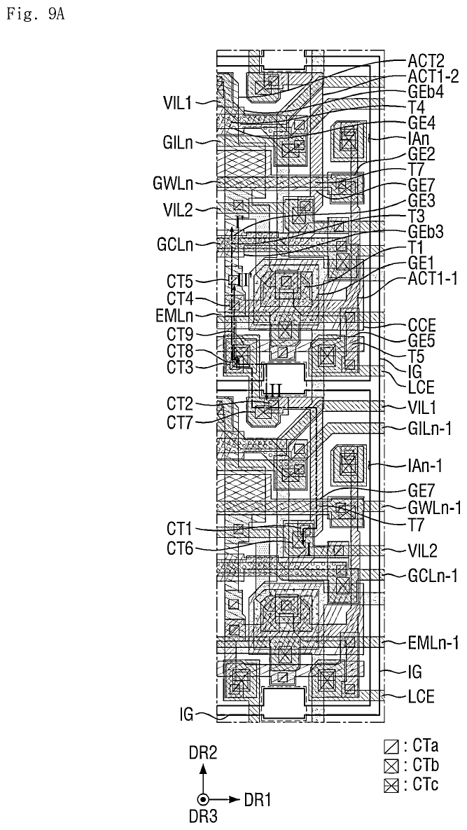

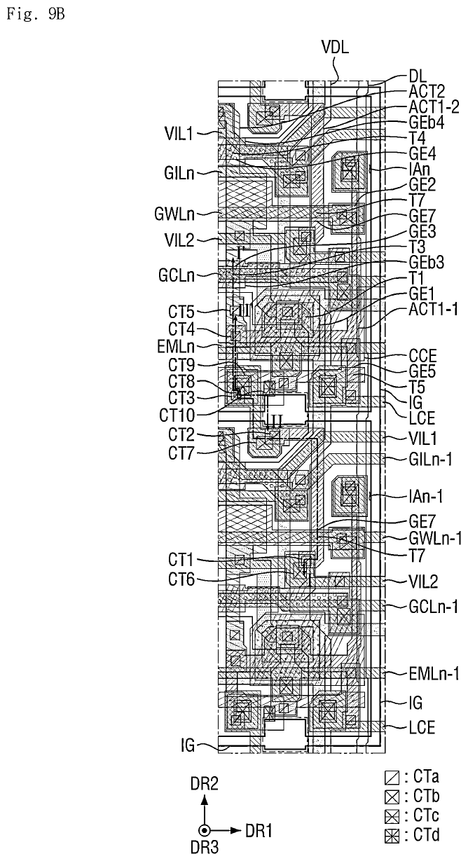

In an embodiment, as illustrated in FIG. 7 or FIG. 9A to be described later, in a plan view, each of some of the pinhole areas PHA described above may be an area surrounded by an intermediate connection electrode CEb, a fifth gate electrode GE5 (or a sixth gate electrode GE6, or a pattern including the fifth gate electrode GE5 and the sixth gate electrode GE6), a lower light blocking layer BML, and a second first active layer (hereinafter, will be referred to as “(1-2)th active layer”) ACT1-2. Alternatively, in a plan view, each of some of the pinhole areas PHA described above may be located in an area surrounded by the intermediate connection electrode CEb, the fifth gate electrode GE5 (or the sixth gate electrode GE6, or the pattern including the fifth gate electrode GE5 and the sixth gate electrode GE6), the lower light blocking layer BML, and the (1-2)^{th} active layer ACT1-2.

In an embodiment, as illustrated in FIG. 7, in a plan view, each of some of the pinhole areas PHA described above may be disposed in an area surrounded by a power connection electrode LCE, the lower light blocking layer BML, and a first initialization voltage line VIL1. Alternatively, in a plan view, each of some of the pinhole areas PHA described above may be located in an area surrounded by the power connection electrode LCE, the lower light blocking layer BML, and the first initialization voltage line VIL1.

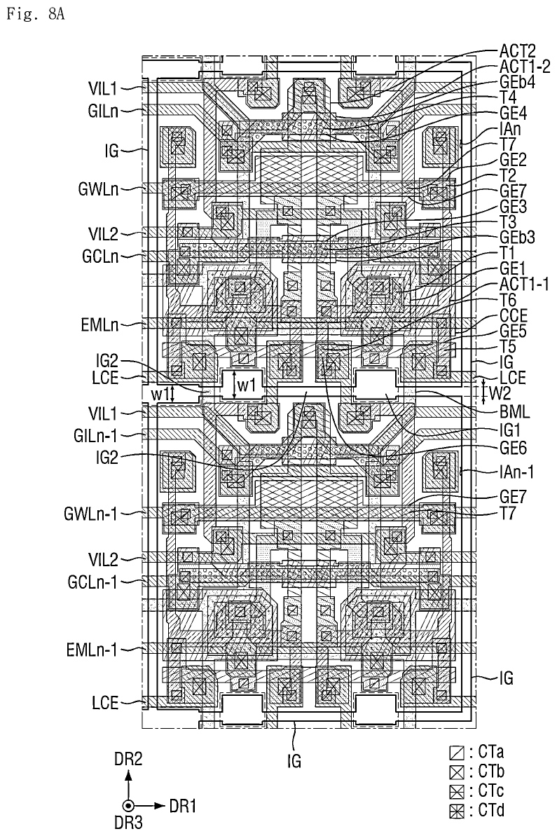

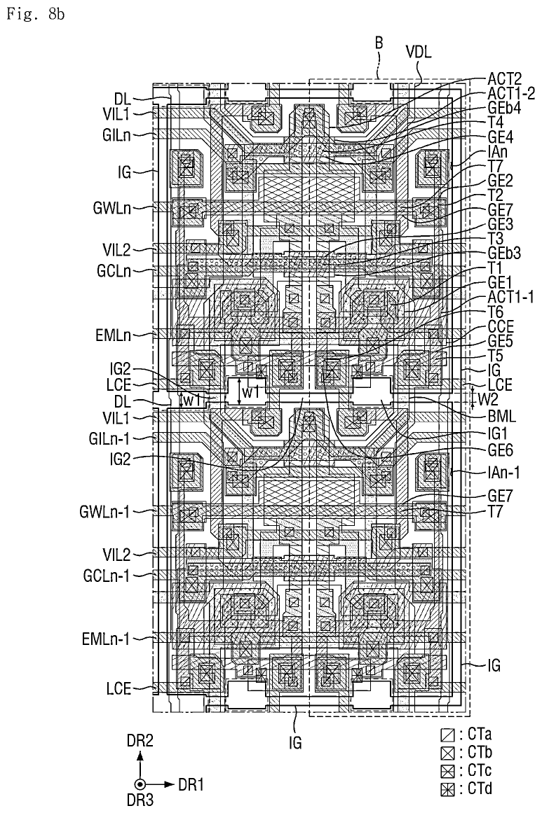

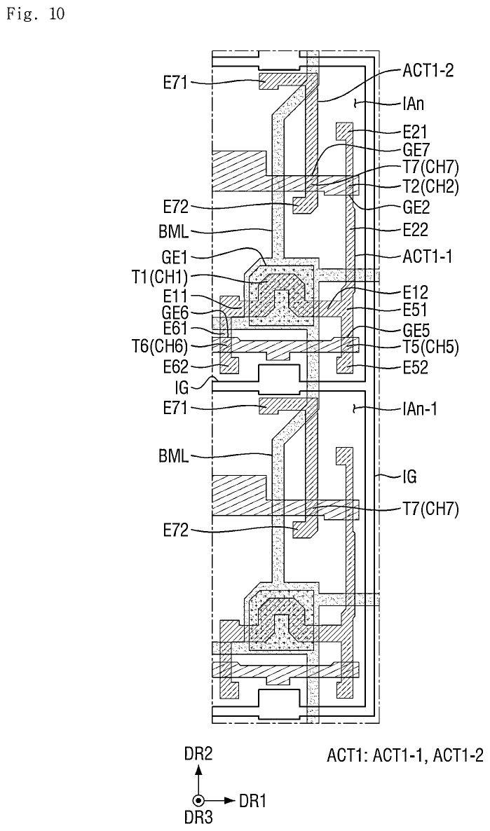

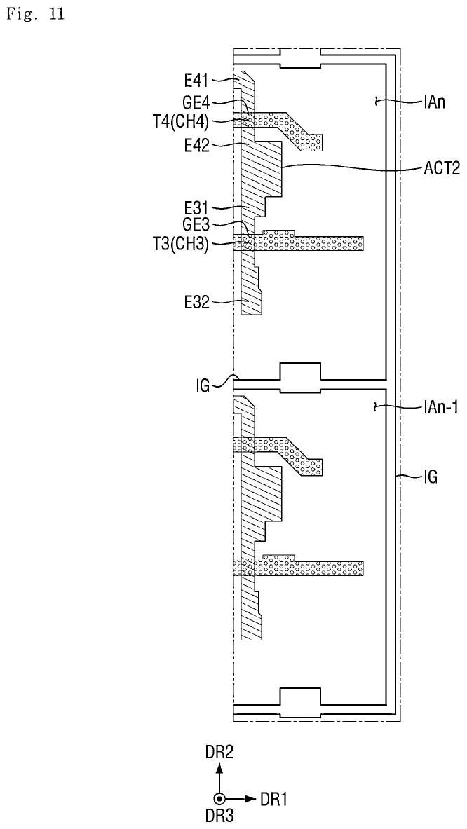

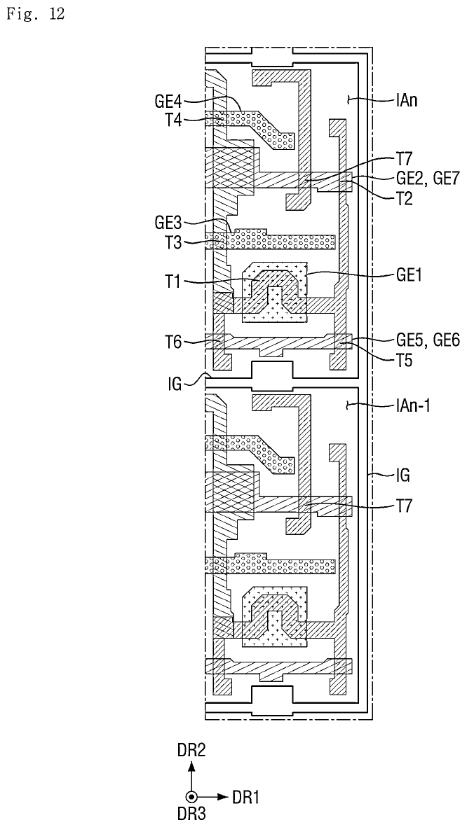

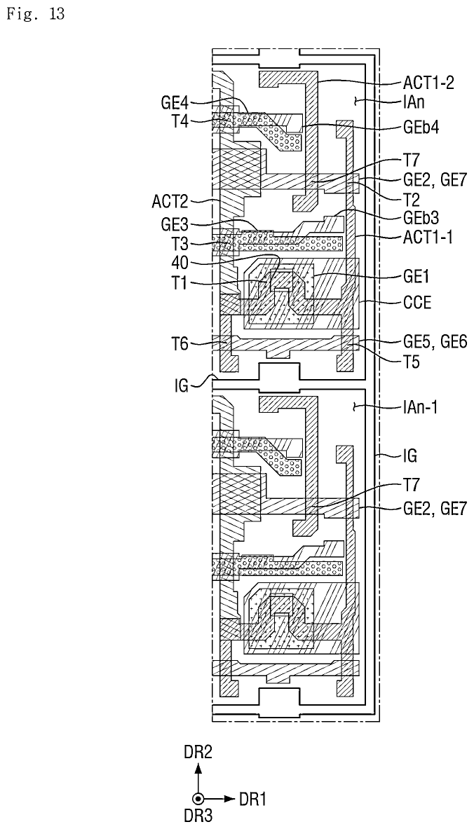

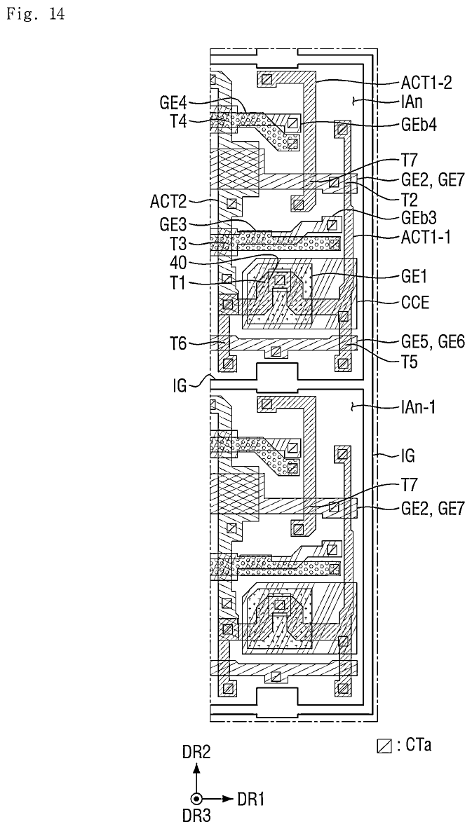

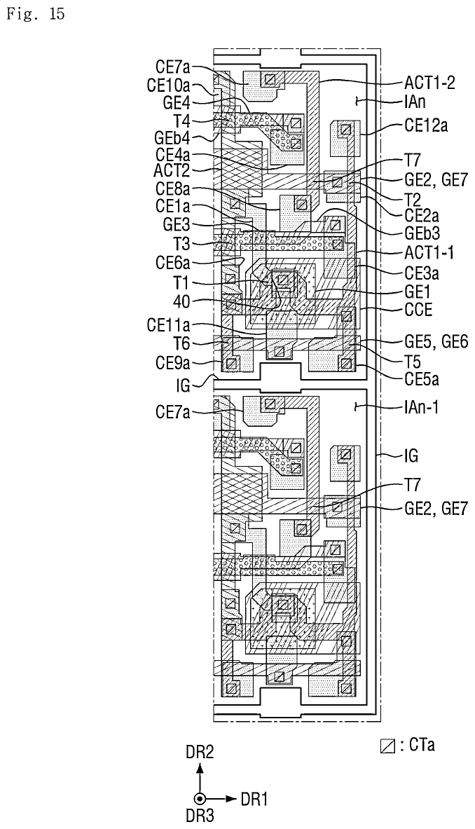

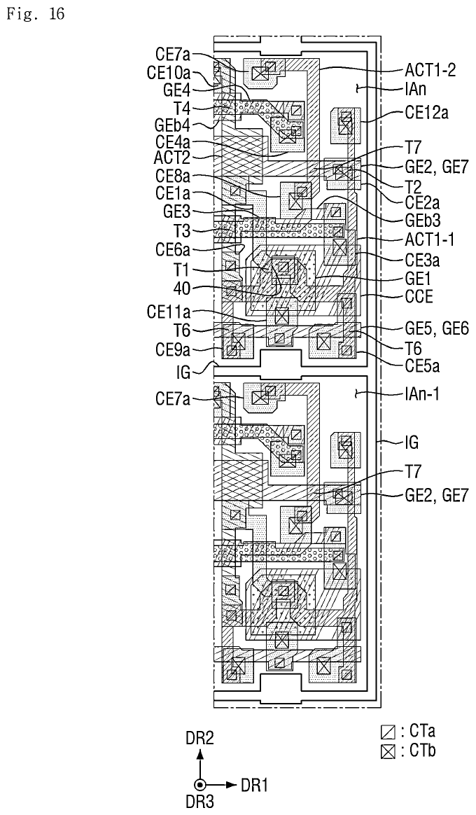

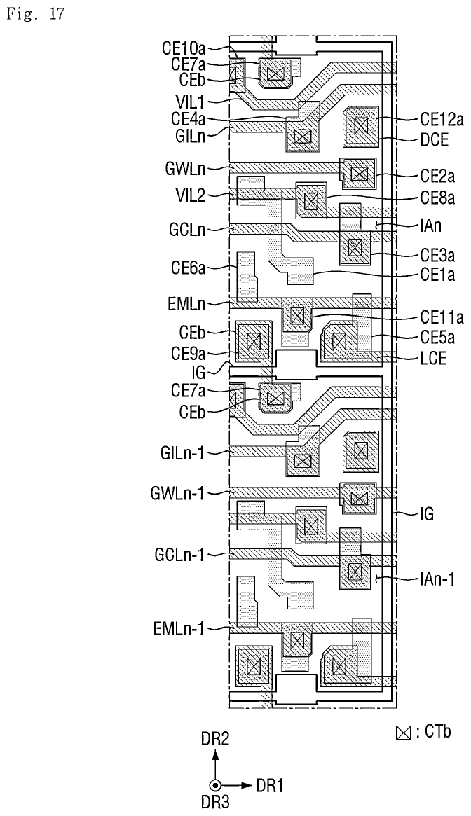

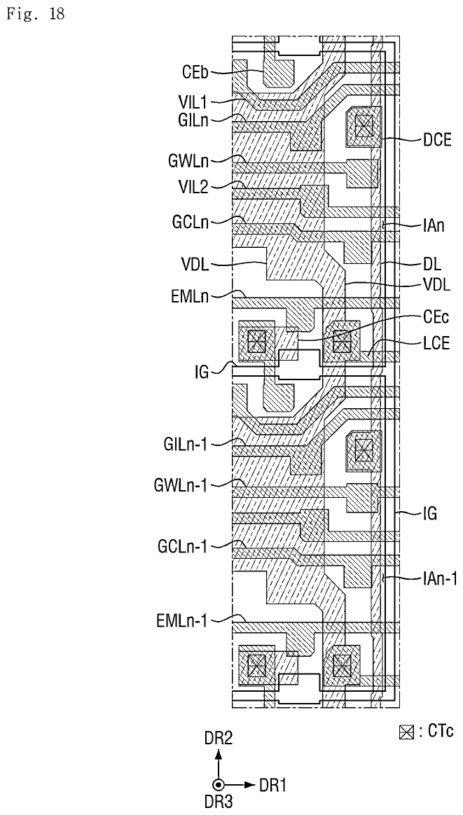

FIG. 8A is an enlarged view of portion A of FIG. 7. FIG. 8B illustrates an eighth conductive layer added to FIG. 8A. FIG. 9A is an enlarged view of portion B of FIG. 8B. FIG. 9B illustrates the eighth conductive layer added to FIG. 9A. FIG. 10 illustrates only a first conductive layer, a second conductive layer, and a third conductive layer among elements of FIG. 9B. FIG. 11 illustrates only a sixth conductive layer and a seventh conductive layer among the elements of FIG. 9B. FIG. 12 is a plan view illustrating only the second conductive layer, the third conductive layer, a fifth conductive layer, and the sixth conductive layer among the elements of FIG. 9B. FIG. 13 is a plan view illustrating only the second through sixth conductive layers among the elements of FIG. 9B. FIG. 14 is a plan view illustrating only the second through sixth conductive layers and first type contact holes CTa among the elements of FIG. 9B. FIG. 15 is a plan view illustrating only the second through seventh conductive layers and the first type contact holes CTa among the elements of FIG. 9B. FIG. 16 is a plan view illustrating only the second through seventh conductive layers, the first type contact holes CTa, and second type contact holes CTb among the elements of FIG. 9B. FIG. 17 is a plan view illustrating only the seventh conductive layer, the eighth conductive layer, and the second type contact holes CTb among the elements of FIG. 9b. FIG. 18 is a plan view illustrating only the eighth conductive layer, a ninth conductive layer and third type contact holes CTc among the elements of FIG. 9B.

As illustrated in FIGS. 8A and 8B, contact holes may be divided into the first type contact holes CTa, the second type contact holes CTb, the third type contact holes CTc, and a fourth type contact holes CTd. The first type contact holes CTa may be contact holes for connecting the seventh conductive layer to be described later and a conductive layer (e.g., at least one of the second through sixth conductive layers) directly under the seventh conductive layer. The second type contact holes CTb may be contact holes for connecting the eighth conductive layer and a conductive layer (e.g., the seventh conductive layer) directly under the eighth conductive layer. The third type contact holes CTc may be contact holes for connecting the ninth conductive layer and a conductive layer (e.g., the eighth conductive layer) directly under the ninth conductive layer. The fourth type contact holes CTd may be contact holes for connecting a tenth conductive layer and a conductive layer (e.g., the ninth conductive layer) directly under the tenth conductive layer.

Unless otherwise specified, each conductive layer will be described below, focusing on conductive layers included in or connected to an n^{th} pixel PXn.

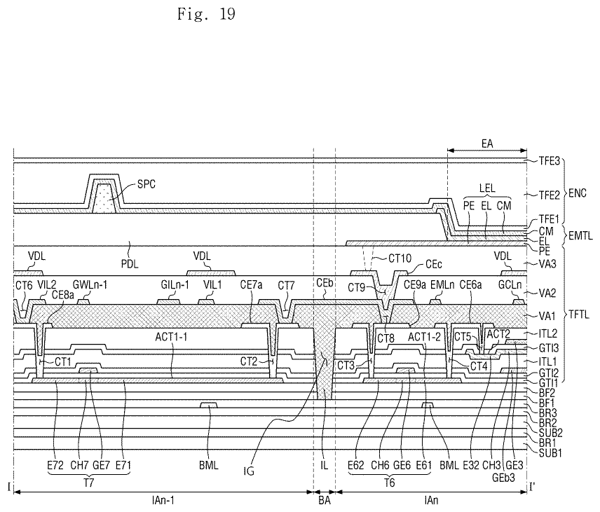

The first conductive layer may be disposed on a first substrate. The first conductive layer may include the lower light blocking layer BML as illustrated in FIGS. 9A through 10. The lower light blocking layer BML may overlap an active layer of the first transistor T1 to prevent generation of leakage current due to incidence of light to the active layer of the first transistor T1 which is a driving transistor. In an embodiment, as shown in FIGS. 9A and 10, the lower light blocking layer BML overlaps only the active layer of the first transistor T1. However, the present disclosure is not limited thereto. In an alternative embodiment, for example, the lower light blocking layer BML may overlap not only the active layer of the first transistor T1 but also an active layer of at least one of the second through seventh transistors T2 through T7. The lower light blocking layer BML may be covered by a third barrier layer BR3 (see FIG. 19). The lower light blocking layer BML may be a single layer or a multilayer including mat least one selected from molybdenum (Mo), aluminum (Al), chromium (Cr), gold (Au), titanium (Ti), nickel (Ni), neodymium (Ne), copper (Cu), and alloys thereof. In addition, the lower light blocking layer BML may be supplied with static power. Therefore, the lower light blocking layer BML may not electrically float, and electrical characteristics of transistors (e.g., the first transistor) on the lower light blocking layer BML may be stabilized.

The second conductive layer may be disposed on the first conductive layer along a third direction DR3. An insulating layer may be disposed between the first conductive layer and the second conductive layer. The second conductive layer may include a first active layer ACT1 as in the example illustrated in FIGS. 9A through 10 and 12. The first active layer ACT1 may include a first first active layer (hereinafter, will be referred to as “(1-1)th active layer”) ACT1-1 and the (1-2)^{th} active layer ACT1-2.

The (1-1)^{th} active layer ACT1-1 may provide respective channel regions CH1, CH2, CH5 and CH6, first electrodes E11, E21, E51 and E61, and second electrodes E12, E22, E52 and E62 of the first transistor T1, the second transistor T2, the fifth transistor T5 and the sixth transistor T6.

The (1-2)^{th} active layer ACT1-2 may provide a seventh channel region CH7, a first electrode E71 and a second electrode E72 of the seventh transistor T7.

Each of the (1-1)^{th} active layer ACT1-1 and the (1-2)^{th} active layer ACT1-2 may be a semiconductor layer including or made of low-temperature polycrystalline silicon (LTPS).

The third conductive layer may be disposed on the second conductive layer in the third direction DR3. An insulating layer may be disposed between the second conductive layer and the third conductive layer. The third conductive layer may include a first gate electrode GEL, a second gate electrode GE2, the fifth gate electrode GE5, the sixth gate electrode GE6, and a seventh gate electrode GE7 as illustrated in FIGS. 9A through 10. Here, the second gate electrode GE2 and the seventh gate electrode GE7 may be integrally formed with each other as a single unitary and indivisible part, and the fifth gate electrode GE5 and the sixth gate electrode GE6 may be integrally formed with each other as a single unitary and indivisible part.

The first, second, fifth and sixth gate electrodes GE1, GE2, GE5 and GE6 may overlap the (1-1)^{th} active layer ACT1-1.

The seventh gate electrode GE7 may overlap the (1-2)^{th} active layer ACT1-2.

The channel regions CH1, CH2, CH5, CH6 and CH7 of the first, second, fifth, sixth and seventh transistors T1, T2, T5, T6 and T7 may be respectively formed in overlapping regions between the first, second, fifth, sixth and seventh gate electrodes GE1, GE2, GE5, GE6 and GE7 and the first active layer ACT1.

The first transistor T1 may include the first gate electrode GE1, the first electrode E11, the second electrode E21, and a first channel region CH1. The second transistor T2 may include the second gate electrode GE2, the first electrode E21, the second electrode E22, and a second channel region CH2. The fifth transistor T5 may include the fifth gate electrode GE5, the first electrode E51, the second electrode E52, and a fifth channel region CH5. The sixth transistor T6 may include the sixth gate electrode GE6, the first electrode E61, the second electrode E62, and a sixth channel region CH6. The seventh transistor T7 may include the seventh gate electrode GE7, the first electrode E71, the second electrode E72, and the seventh channel region CH7.

The fourth conductive layer may be disposed on the third conductive layer in the third direction DR3. An insulating layer may be disposed between the third conductive layer and the fourth conductive layer. In an embodiment, the fourth conductive layer may include a capacitor electrode CCE, a third counter gate electrode GEb3, and a fourth counter gate electrode GEb4 as illustrated in FIGS. 9B and 13.

The capacitor electrode CCE may overlap the first gate electrode GE1. The capacitor Cst may be formed in an area where the capacitor electrode CCE and the first gate electrode GE1 overlap. In an embodiment, for example, the capacitor electrode CCE and the first gate electrode GE1 may correspond to a first electrode and a second electrode of the capacitor Cst, respectively.

The third counter gate electrode GEb3 may overlap a second active layer ACT2 and the third gate electrode GE3. In an embodiment, for example, the third counter gate electrode GEb3 may face the third gate electrode GE3 with the second active layer ACT2 interposed between them.

The fourth counter gate electrode GEb4 may overlap the second active layer ACT2 and the fourth gate electrode GE4. In an embodiment, for example, the fourth counter gate electrode GEb4 may face the fourth gate electrode GE4 with the second active layer ACT2 interposed between them.

The fifth conductive layer may be disposed on the fourth conductive layer in the third direction DR3. An insulating layer may be disposed between the fourth conductive layer and the fifth conductive layer. In an embodiment, the fifth conductive layer may include the second active layer ACT2 as illustrated in FIGS. 9B, 11 and 12. The second active layer ACT2 may provide respective channel regions CH3 and CH4, first electrodes E31 and E41, and second electrodes E32 and E42 of the third transistor T3 and the fourth transistor T4.

The second active layer ACT2 may be, for example, an oxide-based semiconductor.

The sixth conductive layer may be disposed on the fifth conductive layer in the third direction DR3. An insulating layer may be disposed between the fifth conductive layer and the sixth conductive layer. In an embodiment, the sixth conductive layer may include a third gate electrode GE3 and a fourth gate electrode GE4 as illustrated in FIGS. 9B, 11 and 12.

The third gate electrode GE3 and the fourth gate electrode GE4 may overlap the second active layer ACT2.

The channel regions CH3 and CH4 of the third and fourth transistors T3 and T4 may be respectively formed in overlapping regions between the third and fourth gate electrodes GE3 and GE4 and the second active layer ACT2.

The third transistor T3 may include the third gate electrode GE3, the first electrode E31, the second electrode E32, and a third channel region CH3. The fourth transistor T4 may include the fourth gate electrode GE4, the first electrode E41, the second electrode E42, and a fourth channel region CH4.

The seventh conductive layer may be disposed on the sixth conductive layer in the third direction DR3. An insulating layer may be disposed between the sixth conductive layer and the seventh conductive layer. In an embodiment, the seventh conductive layer may include a plurality of lower connection electrodes as illustrated in FIGS. 9B and 15 through 17.

A first lower connection electrode CE1a may be connected to the first gate electrode GE1 through a first type contact hole of the insulating layer and a hole 40 of the capacitor electrode CCE. In addition, the first lower connection electrode CE1a may be connected to the first electrode E31 of the third transistor T3 and the second electrode E42 of the fourth transistor T4 through a first type contact hole of the insulating layer.

A second lower connection electrode CE2a may be connected to the second gate electrode GE2 and the seventh gate electrode GE7 through a first type contact hole of the insulating layer.

A third lower connection electrode CE3a may be connected to the third gate electrode GE3 through a first type contact hole of the insulating layer. In addition, the third lower connection electrode CE3a may be connected to the third counter gate electrode GEb3 through a first type contact hole of the insulating layer.

A fourth lower connection electrode CE4a may be connected to the fourth gate electrode GE4 through a first type contact hole of the insulating layer. In addition, the fourth lower connection electrode CE4a may be connected to the fourth counter gate electrode GEb4 through a first type contact hole of the insulating layer.

A fifth lower connection electrode CE5a may be connected to the second electrode E52 of the fifth transistor T5 through a first type contact hole of the insulating layer. In addition, the fifth lower connection electrode CE5a may be connected to the capacitor electrode CCE through a first type contact hole of the insulating layer.

A sixth lower connection electrode CE6a may be connected to the first electrode E61 of the sixth transistor T6 and the first electrode E11 of the first transistor T1 through a first type contact hole of the insulating layer. In addition, the sixth lower connection electrode CE6a may be connected to the second electrode E32 of the third transistor T3 through a first type contact hole of the insulating layer. In other words, the sixth lower connection electrode CE6a may connect the (1-1)^{th} active layer ACT1-1 and the second active layer ACT2 to each other.

A seventh lower connection electrode CE7a may be connected to the first electrode E71 of the seventh transistor T7 through a first type contact hole of the insulating layer.

An eighth lower connection electrode CE8a may be connected to the second electrode E72 of the seventh transistor T7 through a first type contact hole of the insulating layer.

A ninth lower connection electrode CE9a may be connected to the second electrode E62 of the sixth transistor T6 through a first type contact hole of the insulating layer.

A tenth lower connection electrode CE10a may be connected to the first electrode E41 of the fourth transistor T4 through a first type contact hole of the insulating layer.

An eleventh lower connection electrode CET1a may be connected to the fifth gate electrode GE5 and the sixth gate electrode GE6 through a first type contact hole of the insulating layer.

A twelfth lower connection electrode CE12a may be connected to the first electrode E21 of the second transistor T2 through a first type contact hole of the insulating layer.

The eighth conductive layer may be disposed on the seventh conductive layer in the third direction DR3. An insulating layer may be disposed between the seventh conductive layer and the eighth conductive layer. In an embodiment, as illustrated in FIGS. 9B, 17 and 18, the eighth conductive layer may include an n^{th} first gate line GWLn, an n^{th} second gate line GCLn, an n^{th} third gate line GILn, an n^{th} fourth gate line GBLn (e.g., an (n−1)^{th} first gate line GWLn−1), an n^{th} emission control line EMLn, the first initialization voltage line VIL1, a second initialization voltage line VIL2, a data connection electrode DCE, the power connection electrode LCE, and the intermediate connection electrode CEb.

The n^{th} first gate line GWLn may be connected to the second lower connection electrode CE2a through a second type contact hole of the insulating layer.

The n^{th} second gate line GCLn may be connected to the third lower connection electrode CE3a through a second type contact hole of the insulating layer.

The n^{th} third gate line GILn may be connected to the fourth lower connection electrode CE4a through a second type contact hole of the insulating layer.

The n^{th} fourth gate line GBLn (e.g., the (n−1)^{th} first gate line GWLn−1) may be connected to the second lower connection electrode CE2a of an (n−1)^{th} isolation area IAn−1 through a second type contact hole of the insulating layer.

The n^{th} emission control line EMLn may be connected to the eleventh lower connection electrode CE11a through a second type contact hole of the insulating layer.

The first initialization voltage line VIL1 may be connected to the tenth lower connection electrode CE10a through a second type contact hole of the insulating layer.

The second initialization voltage line VIL2 may be connected to the eighth lower connection electrode CE8a through a second type contact hole of the insulating layer.

The data connection electrode DCE may be connected to the twelfth lower connection electrode CE12a through a second type contact hole of the insulating layer.

The power connection electrode LCE may be connected to the fifth lower connection electrode CE5a through a second type contact hole of the insulating layer.

The intermediate connection electrode CEb may be connected to the seventh lower connection electrode CE7a through a second type contact hole of the insulating layer. In addition, the intermediate connection electrode CEb may be connected to the ninth lower connection electrode CE9a through a second type contact hole of the insulating layer. In addition, the intermediate connection electrode CEb may overlap the isolation groove. The sixth transistor T6 of an n^{th} isolation area IAn and the seventh transistor T7 of the (n−1)^{th} isolation area IAn−1 may be connected to each other through the intermediate connection electrode CEb.

The ninth conductive layer may be disposed on the eighth conductive layer in the third direction DR3. An insulating layer may be disposed between the eighth conductive layer and the ninth conductive layer. In an embodiment, the ninth conductive layer may include a first driving voltage line VDL, a data line DL, and an upper connection electrode CEc as illustrated in FIGS. 9B and 18.

The first driving voltage line VDL may be connected to the power connection electrode LCE through a third type contact hole of the insulating layer.

The data line DL may be connected to the data connection electrode DCE through a third type contact hole of the insulating layer.

The upper connection electrode CEc may be connected to the intermediate connection electrode CEb through a third type contact hole of the insulating layer.

The tenth conductive layer may be disposed on the ninth conductive layer in the third direction DR3. An insulating layer may be disposed between the ninth conductive layer and the tenth conductive layer. The tenth conductive layer may include, for example, a pixel electrode PE (see FIG. 19).

A portion of the pixel electrode PE may be exposed by a bank which will be described later. In an embodiment, for example, the bank may be provided with or define an opening EA (hereinafter, referred to as an emission area) exposing a portion of the pixel electrode PE. The emission area EA may correspond to a portion excluding edges of the pixel electrode PE. A light emitting layer may be disposed on the pixel electrode PE corresponding to the emission area EA. The pixel electrode PE may be connected to the upper connection electrode CEc through a fourth type contact hole of the insulating layer.

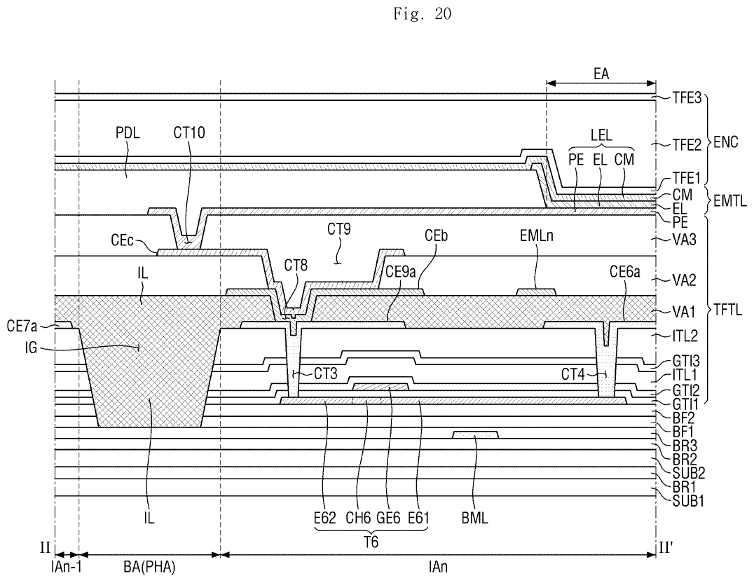

FIG. 19 is a cross-sectional view of the display device 10 according to an embodiment, taken along line I-I′ of FIG. 9B. FIG. 20 is a cross-sectional view of the display device 10 according to an embodiment, taken along line II-II′ of FIG. 9B.

The display device 10 may include a first substrate SUB1, a first barrier layer BR1, a second substrate SUB2, a second barrier layer BR2, the lower light blocking layer BML, the third barrier layer BR3, a first buffer layer BF1, a second buffer layer BF2, a thin-film transistor layer TFTL, a light emitting element layer EMTL, and an encapsulation layer ENC. The first barrier layer BR1, the second substrate SUB2, the second barrier layer BR2, the lower light blocking layer BML, the third barrier layer BR3, the first buffer layer BF1, the second buffer layer BF2, the thin-film transistor layer TFTL, the light emitting element layer EMTL, and the encapsulation layer ENC may be sequentially disposed on the first substrate SUB1 in the third direction DR3. Here, the thin-film transistor layer TFTL may include the pixel circuits PC described above.

The first substrate SUB1 may be a rigid substrate or a flexible substrate that can be bent, folded, or rolled. The substrate SUB may including or be made of an insulating material such as glass, quartz, or polymer resin. The polymer material may be, for example, polyethersulfone (PES), polyacrylate (PA), polyarylate (PAR), polyetherimide (PET), polyethylene naphthalate (PEN), polyethylene terepthalate (PET), polyphenylene sulfide (PPS), polyallylate, polyimide (PT), polycarbonate (PC), cellulose triacetate (CAT), cellulose acetate propionate (CAP), or a combination thereof. Alternatively, the first substrate SUB1 may include a metal material.

As illustrated in FIGS. 19 and 20, the first barrier layer BR1 may be disposed on the first substrate SUB1. In an embodiment, for example, the first barrier layer BR1 may be disposed on the entire surface of the first substrate SUB1. The first barrier layer BR1 may be a layer for protecting the thin-film transistors T1 through T7 of the thin-film transistor layer TFTL and a light emitting layer EL of the light emitting element layer EMTL from moisture introduced through the first substrate SUB1 which is vulnerable to moisture penetration. The first barrier layer BR1 may be defined by or composed of a plurality of inorganic layers stacked alternately. In an embodiment, for example, the first barrier layer BR1 may be a multilayer in which inorganic layers, each including at least one selected from an amorphous silicon layer, a silicon nitride layer, a silicon oxynitride layer, a silicon oxide layer, a titanium oxide layer, and an aluminum oxide layer, are alternately stacked.

The second substrate SUB2 may be disposed on the first barrier layer BR1. The second substrate SUB2 may include a same material and have a same structure as the first substrate SUB1 described above. In an embodiment, for example, the second substrate SUB2 may be disposed on the entire surface of the first substrate including the first barrier layer BR1.

The second barrier layer BR2 may be disposed on the second substrate SUB2. In an embodiment, for example, the second barrier layer BR2 may be disposed on the entire surface of the first substrate SUB1 including the second substrate SUB2. The second barrier layer BR2 may include a same material and have a same structure as the first barrier layer BR1 described above.

The lower light blocking layer BML may be disposed on the second barrier layer BR2. In an embodiment, as described above, the lower light blocking layer BML may overlap the active layer (e.g., ACT1-1) of the first transistor T1 which is a driving transistor.

The third barrier layer BR3 may be disposed on the lower light blocking layer BML. In an embodiment, for example, the third barrier layer BR3 may be disposed on the entire surface of the first substrate SUB1 including the second barrier layer BR2. The third barrier layer BR3 may include a same material and have a same structure as the first barrier layer BR1 described above.

The first buffer layer BFT may be disposed on the third barrier layer BR3. In an embodiment, for example, the first buffer layer BFT may be disposed on the entire surface of the first substrate SUB1 including the third barrier layer BR3. The first buffer layer BFT may be a layer for protecting the thin-film transistors T1 through T7 of the thin-film transistor layer TFTL and the light emitting layer EL of the light emitting element layer EMTL from moisture introduced through the first and second substrates SUB1 and SUB2 which are vulnerable to moisture penetration. The first buffer layer BFT may be composed a plurality of inorganic layers stacked alternately. In an embodiment, for example, the first buffer layer BFT may be a multilayer in which inorganic layers, each including at least one selected from a silicon nitride layer, a silicon oxynitride layer, a silicon oxide layer, a titanium oxide layer, and an aluminum oxide layer, are alternately stacked.

The second buffer layer BF2 may be disposed on the first buffer layer BFT. In an embodiment, for example, the second buffer layer BF2 may be disposed on the entire surface of the first substrate SUB1 including the first buffer layer BF1. The second buffer layer BF2 may include a same material and have a same structure as the first buffer layer BF1 described above.

The second conductive layer may be disposed on the second buffer layer BF2. In an embodiment, for example, as illustrated in FIGS. 19 and 20, the (1-1)^{th} active layer ACT1-1 and the (1-2)^{th} active layer ACT1-2 may be disposed on the second buffer layer BF2. On the second buffer layer BF2, the (1-1)^{th} active layer ACT1-1 may be disposed in the (n−1)^{th} isolation area IAn−1 of the substrate SUB, and the (1-2)^{th} active layer ACT1-2 may be disposed in the n^{th} isolation area IAn of the substrate SUB. The (1-1)^{th} active layer ACT1-1 may include the first electrode E71, the second electrode E72 and the seventh channel region CH7 of the seventh transistor T7. The (1-2)^{th} active layer ACT1-2 may include the first electrode E61, the second electrode E62 and the sixth channel region CH6 of the sixth transistor T6.

The (1-1)^{th} active layer ACT1-1 and the (1-2)^{th} active layer ACT1-2 may be active layers including or made of low-temperature polycrystalline silicon (LTPS).

A first gate insulating layer GTI1 may be disposed on the second conductive layer. In an embodiment, for example, as illustrated in FIGS. 19 and 20, the first gate insulating layer GTI1 may be disposed on the (1-1)^{th} active layer ACT1-1 and the (1-2)^{th} active layer ACT1-2. In an embodiment, for example, the first gate insulating layer GTI1 may be disposed on the entire surface of the first substrate SUB1 including the second conductive layer.

The first gate insulating layer GTI1 may include at least one selected from tetraethoxysilane (TEOS), silicon nitride (SiNx), and silicon oxide (SiO₂). In an embodiment, for example, the first gate insulating layer GTI1 may have a double layer structure in which a silicon nitride layer having a thickness of 40 nanometers (nm) and a tetraethoxysilane layer having a thickness of 80 nm are sequentially stacked.

The third conductive layer may be disposed on the first gate insulating layer GTI1. In an embodiment, for example, as illustrated in FIGS. 19 and 20, the seventh gate electrode GE7 and the sixth gate electrode GE6 may be disposed on the first gate insulating layer GTI1. On the first gate insulating layer GTI1, the seventh gate electrode GE7 may be disposed in the (n−1)^{th} isolation area IAn−1 to overlap the seventh channel region CH7 of the (1-2)^{th} active layer ACT1-2, and the sixth gate electrode GE6 may be disposed in the n^{th} isolation area IAn to overlap the sixth channel region CH6 of the (1-1)^{th} active layer ACT1-1.

The third conductive layer may be a single layer or a multilayer, each layer including at least one selected from molybdenum (Mo), copper (Cu), and titanium (Ti).

A second gate insulating layer GTI2 may be disposed on the third conductive layer. In an embodiment, for example, as illustrated in FIGS. 19 and 20, the second gate insulating layer GTI2 may be disposed on the seventh gate electrode GE7 and the sixth gate electrode GE6. In an embodiment, for example, the second gate insulating layer GTI2 may be disposed on the entire surface of the first substrate SUB1 including the third conductive layer.

The second gate insulating layer GTI2 may include a same material and have a same structure as the first gate insulating layer GTI1 described above.

The fourth conductive layer may be disposed on the second gate insulating layer GTI2. In an embodiment, for example, as illustrated in FIGS. 19 and 20, the third counter gate electrode GEb3 may be disposed on the second gate insulating layer GTI2.

The fourth conductive layer may include a same material and have a same structure as the third conductive layer described above.

A first interlayer insulating layer ITL1 may be disposed on the fourth conductive layer. In an embodiment, for example, as illustrated in FIGS. 19 and 20, the first interlayer insulating layer ITL1 may be disposed on the third counter gate electrode GEb3. In an embodiment, for example, the first interlayer insulating layer ITL1 may be disposed on the entire surface of the first substrate SUB1 including the fourth conductive layer.

The first interlayer insulating layer ITL1 may include an inorganic layer, for example, a silicon nitride layer, a silicon oxynitride layer, a silicon oxide layer, a titanium oxide layer, or an aluminum oxide layer. The first interlayer insulating layer ITL1 may include a plurality of inorganic layers.

The fifth conductive layer may be disposed on the first interlayer insulating layer ITL1. In an embodiment, for example, as illustrated in FIGS. 19 and 20, the second active layer ACT2 may be disposed on the first interlayer insulating layer ITL1. On the first interlayer insulating layer ITL1, the second active layer ACT2 may be disposed in the n^{th} isolation area IAn to overlap the third counter gate electrode GEb3. The second active layer ACT2 may include the second electrode E32 and the third channel region CH3 of the third transistor T3. Here, the third channel region CH3 of the second active layer ACT2 may overlap the third counter gate electrode GEb3.

The second active layer ACT2 may be an oxide-based active layer. In an embodiment, for example, the second active layer ACT2 may be an oxide semiconductor layer including indium-gallium-zinc-oxide (IGZO) or indium-gallium-zinc-tin oxide (IGZTO).

A third gate insulating layer GTI3 may be disposed on the fifth conductive layer. In an embodiment, for example, as illustrated in FIGS. 19 and 20, the third gate insulating layer GTI3 may be disposed on the second active layer ACT2. In an embodiment, for example, the third gate insulating layer GTI3 may be disposed on the entire surface of the first substrate SUB1 including the fifth conductive layer.

The third gate insulating layer GTI3 may include a same material and have a same structure as the first gate insulating layer GTI1 described above.

The sixth conductive layer may be disposed on the third gate insulating layer GTI3. In an embodiment, for example, as illustrated in FIGS. 19 and 20, the third gate electrode GE3 may be disposed on the third gate insulating layer GTI3. On the third gate insulating layer GTI3, the third gate electrode GE3 may be disposed in the n^{th} isolation area IAn to overlap the third channel region CH3 of the second active layer ACT2.

The sixth conductive layer may include a same material and have a same structure as the third conductive layer described above.

A second interlayer insulating layer ITL2 may be disposed on the sixth conductive layer. In an embodiment, for example, as illustrated in FIGS. 19 and 20, the second interlayer insulating layer ITL2 may be disposed on the third gate electrode GE3. In an embodiment, for example, the second interlayer insulating layer ITL2 may be disposed on the entire surface of the first substrate SUB1 including the sixth conductive layer.

The second interlayer insulating layer ITL2 may include a same material and have a same structure as the first interlayer insulating layer ITL1 described above.

The seventh conductive layer may be disposed on the second interlayer insulating layer ITL2. In an embodiment, for example, as illustrated in FIGS. 19 and 20, the eighth lower connection electrode CE8a, the seventh lower connection electrode CE7a, the ninth lower connection electrode CE9a, and the sixth lower connection electrode CE6a may be disposed on the second interlayer insulating layer ITL2. On the second interlayer insulating layer ITL2, the eighth lower connection electrode CE8a and the seventh lower connection electrode CE7a may be disposed in the (n−1)^{th} isolation area IAn−1, and the ninth lower connection electrode CE9a and the sixth lower connection electrode CE6a may be disposed in the n^{th} isolation area IAn. In the (n−1)^{th} isolation area IAn−1, the eighth lower connection electrode CE8a may be connected to the second electrode E72 of the (1-1)^{th} active layer ACT1-1 (e.g., the second electrode E72 of the seventh transistor T7) through a first contact hole CT1 penetrating the second interlayer insulating layer ITL2, the third gate insulating layer GTI3, the first interlayer insulating layer ITL1, the second gate insulating layer GTI2 and the first gate insulating layer GTI1. Here, a hole penetrating a layer means a hole defined or formed entirely through the layer in a thickness direction thereof. In the (n−1)^{th} isolation area IAn−1, the seventh lower connection electrode CE7a may be connected to the first electrode E71 of the (1-1)^{th} active layer ACT1-1 (e.g., the first electrode E71 of the seventh transistor T7) through a second contact hole CT2 penetrating the second interlayer insulating layer ITL2, the third gate insulating layer GTI3, the first interlayer insulating layer ITL1, the second gate insulating layer GTI2 and the first gate insulating layer GTI1. In the n^{th} isolation area IAn, the ninth lower connection electrode CE9a may be connected to the second electrode E62 of the (1-2)^{th} active layer ACT1-2 (e.g., the second electrode E62 of the sixth transistor T6) through a third contact hole CT3 penetrating the second interlayer insulating layer ITL2, the third gate insulating layer GTI3, the first interlayer insulating layer ITL1, the second gate insulating layer GTI2 and the first gate insulating layer GTI1. In the n^{th} isolation area IAn, the sixth lower connection electrode CE6a may be connected to the second electrode E61 of the (1-2)^{th} active layer ACT1-2 (e.g., the first electrode E61 of the sixth transistor T6) through a contact hole CT4 penetrating the second interlayer insulating layer ITL2, the third gate insulating layer GTI3, the first interlayer insulating layer ITL1, the second gate insulating layer GTI2 and the first gate insulating layer GTI1. In addition, in the n^{th} isolation area IAn, the sixth lower connection electrode CE6a may be connected to the second electrode E32 of the second active layer ACT2 (e.g., the second electrode E32 of the third transistor T3) through a fifth contact hole CT5 penetrating the second interlayer insulating layer ITL2 and the third gate insulating layer GTI3. The first through fifth contact holes CT1 through CT5 described above may be first type contact holes CTa.

The seventh conductive layer may include a same material and have a same structure as the third conductive layer described above.

A first planarization layer VA1 may be disposed on the seventh conductive layer. In an embodiment, for example, as illustrated in FIGS. 19 and 20, the first planarization layer VA1 may be disposed on the eighth lower connection electrode CE8a, the seventh lower connection electrode CE7a, the ninth lower connection electrode CE9a, and the sixth lower connection electrode CE6a. The first planarization layer VA1 may be disposed on the entire surface of the first substrate SUB1 including the eighth lower connection electrode CE8a, the seventh lower connection electrode CE7a, the ninth lower connection electrode CE9a, and the sixth lower connection electrode CE6a.

Here, a portion of the first planarization layer VA1 may be disposed in the isolation groove IG defined through the second interlayer insulating layer ITL2, the third gate insulating layer GTI3, the first interlayer insulating layer ITL1, the second gate insulating layer GTI2, the first gate insulating layer GTI1, the second buffer layer BF2, and the first buffer layer BF1. In an embodiment, for example, the isolation groove IG may be a groove defined through insulating layers (e.g., inorganic layers). The isolation groove IG may be disposed, for example, in a boundary area BA of the first substrate SUB1 at a boundary between the isolation areas IAn and IAn−1. A portion of the first planarization layer VA1 which is disposed inside the isolation groove IG and on the isolation groove IG may correspond to an isolation layer IL.

In an embodiment, the isolation layer IL may be disposed only inside the isolation groove IG. In such an embodiment, the first planarization layer VA1 may be a different layer from the isolation layer IL. In an embodiment, for example, the first planarization layer VA1 may be disposed on the isolation layer IL and the second interlayer insulating layer ITL2.

The isolation groove IG may have a greater width in a pinhole area PHA than in the non-pinhole area as illustrated in FIGS. 19 and 20.

The first planarization layer VA1 may include an organic material such as acryl resin, epoxy resin, phenolic resin, polyamide resin, or polyimide resin.

The eighth conductive layer may be disposed on the first planarization layer VA1. In an embodiment, for example, as illustrated in FIGS. 19 and 20, the second initialization voltage line VIL2, the (n−1)^{th} first gate line GWLn−1, an (n−1)^{th} third gate line GILn−1, the first initialization voltage line VIL1, the intermediate connection electrode CEb, the n^{th} emission control line EMLn, and the n^{th} second gate line GCLn may be disposed on the first planarization layer VA1. The second initialization voltage line VIL2 may be connected to the eighth lower connection electrode CE8a through a sixth contact hole CT6 penetrating the first planarization layer VAT. The intermediate connection electrode CEb may be connected to the seventh lower connection electrode CE7a through a seventh contact hole CT7 penetrating the first planarization layer VA1. In addition, the intermediate connection electrode CEb may be connected to the ninth lower connection electrode CE9a through an eighth contact hole CT8 penetrating the first planarization layer VA1. The sixth through eighth contact holes CT6 through CT8 described above may be second type contact holes CTb.

The eighth conductive layer may include a same material and have a same structure as the third conductive layer described above.

A second planarization layer VA2 may be disposed on the eighth conductive layer. In an embodiment, for example, as illustrated in FIGS. 19 and 20, the second planarization layer VA2 may be disposed on the second initialization voltage line VIL2, the (n−1)^{th} first gate line GWLn−1, the (n−1)^{th} third gate line GILn−1, the first initialization voltage line VIL1, the intermediate connection electrode CEb, the n^{th} emission control line EMLn, and the n^{th} second gate line GCLn. The second planarization layer VA2 may be disposed on the entire surface of the first substrate SUB1 including the second initialization voltage line VIL2, the (n−1)^{th} first gate line GWLn−1, the (n−1)^{th} third gate line GILn−1, the first initialization voltage line VIL1, the intermediate connection electrode CEb, the n^{th} emission control line EMLn, and the n^{th} second gate line GCLn.

The second planarization layer VA2 may include a same material and have a same structure as the first planarization layer VA1 described above.

The ninth conductive layer may be disposed on the second planarization layer VA2. In an embodiment, for example, as illustrated in FIGS. 19 and 20, the first driving voltage line VDL and the upper connection electrode CEc may be disposed on the second planarization layer VA2. The upper connection electrode CEc may be connected to the intermediate connection electrode CEb through a ninth contact hole CT9 penetrating the second planarization layer VA2. The ninth contact hole CT9 described above may be a third type contact hole CTc.

The ninth conductive layer may include a same material and have a same structure as the third conductive layer described above.

A third planarization layer VA3 may be disposed on the ninth conductive layer. In an embodiment, for example, as illustrated in FIGS. 19 and 20, the third planarization layer VA3 may be disposed on the first driving voltage line VDL, and the upper connection electrode CEc. The third planarization layer VA3 may be disposed on the entire surface of the first substrate SUB1 including the first driving voltage line VDL, and the upper connection electrode CEc.

The third planarization layer VA3 may include a same material and have a same structure as the first planarization layer VA1 described above.

The light emitting element layer EMTL including the tenth conductive layer may be disposed on the third planarization layer VA3. In an embodiment, for example, as illustrated in FIGS. 19 and 20, a pixel electrode PE may be disposed on the third planarization layer VA3 as the tenth conductive layer. The pixel electrode PE may be connected to the upper connection electrode CEc through a tenth contact hole CT10 penetrating the third planarization layer VA3. In an embodiment, for example, in the n^{th} isolation area IAn, the pixel electrode PE may be connected to the upper connection electrode CEc through the tenth contact hole CT10 described above. The tenth contact hole CT10 described above may be the fourth type contact hole CTd.

The light emitting element layer EMTL described above may further include a plurality of light emitting elements LEL and a bank PDL (or a pixel defining layer) in addition to the above-described tenth conductive layer.

The light emitting elements LEL may include, for example, a first light emitting element, a second light emitting element, and a third light emitting element. The first light emitting element may include a first pixel electrode, a first light emitting layer and a common electrode CM, the second light emitting element may include a second pixel electrode, a second light emitting layer and the common electrode CM, and the third light emitting element may include a third pixel electrode, a light emitting layer and the common electrode CM.

Each of the light emitting elements LEL may include a pixel electrode PE, a light emitting layer EL, and the common electrode CM. An emission area EA is an area where the pixel electrode PE, the light emitting layer EL, and the common electrode CM are sequentially stacked so that holes from the pixel electrode PE and electrons from the common electrode CM are combined with each other in the light emitting layer EL to emit light. In an embodiment, the pixel electrode PE may be an anode of the light emitting element LEL, and the common electrode CM may be a cathode of the light emitting element LEL.

In an embodiment having a top emission structure in which light is emitted in a direction from the light emitting layer EL toward the common electrode CM, the pixel electrode PE may be a single layer of molybdenum (Mo), titanium (Ti), copper (Cu) or aluminum (Al) or, to increase reflectivity, may have a stacked structure (Ti/Al/Ti) of aluminum and titanium, a stacked structure (ITO/Al/ITO) of aluminum and indium tin oxide, a stacked structure (ITO/Ag/ITO) of silver and indium tin oxide, an APC alloy, or a stacked structure (ITO/APC/ITO) of an APC alloy and indium tin oxide. The APC alloy is an alloy of silver (Ag), palladium (Pd), and copper (Cu).

The bank PDL (or pixel defining layer) may define emission areas EA of pixels, in an embodiment, the bank PDL may be disposed on the third planarization layer VA3 to expose a portion of the first pixel electrode PE. The bank PDL may cover edges of the first pixel electrode PE. Although not illustrated, the bank PDL may be disposed in eleventh and twelfth contact holes CT11 and CT12 penetrating the third planarization layer VA3. Therefore, the eleventh and twelfth contact holes CT11 and CT12 penetrating the third planarization layer VA3 may be filled with the bank PDL. The bank PDL may include or be made of an organic layer such as acryl resin, epoxy resin, phenolic resin, polyamide resin, or polyimide resin.

In an embodiment, as illustrated in FIG. 19, a spacer SPC may be disposed on the bank PDL. The spacer SPC may support a mask during a process of manufacturing the light emitting layer EL. The spacer SPC may include or be made of an organic layer such as acryl resin, epoxy resin, phenolic resin, polyamide resin, or polyimide resin.

The light emitting layer EL may be disposed or formed on the pixel electrode PE. The light emitting layer EL may include an organic material to emit light of a predetermined color. In an embodiment, for example, the light emitting layer EL may include a hole transport layer, an organic material layer, and an electron transport layer. The organic material layer may include a host and a dopant. The organic material layer may include a material that emits predetermined light and may be formed using a phosphorescent material or a fluorescent material.

In an embodiment, for example, the organic material layer of the first light emitting layer of a first emission area emitting light of a first color may be a phosphorescent material that includes a host material including carbazole biphenyl (CBP) or 1,3-bis(carbazol-9-yl)benzene (mCP) and a dopant including any one or more of bis(1-phenylisoquinoline)acetylacetonate iridium (PIQIr(acac)), bis(1-phenylquinoline)acetylacetonate iridium (PQIr(acac)), tris (1-phenylquinoline)iridium (PQIr) and octaethylporphyrin platinum (PtOEP). Alternatively, the organic material layer of the first light emitting layer of the first emission area may be a fluorescent material including PBD:Eu(DBM)3(Phen) or perylene. However, the present disclosure is not limited thereto.

The organic material layer of the second light emitting layer of a second emission area emitting light of a second color may be a phosphorescent material that includes a host material including CBP or mCP and a dopant material including Ir(ppy)3(fac tris(2-phenylpyridine)iridium). Alternatively, the organic material layer of the second light emitting layer of the second emission area emitting light of the second color may be a fluorescent material including tris(8-hydroxyquinolino)aluminum (Alq3). However, the present disclosure is not limited thereto.

The organic material layer of the third light emitting layer of a third emission area emitting light of a third color may be, but is not limited to, a phosphorescent material that includes a host material including CBP or mCP and a dopant material including (4,6-F2ppy)2Irpic or L2BD111.

The common electrode CM may be disposed on the first, second and third light emitting layers (e.g., EL). The common electrode CM may cover the first, second and third light emitting layers. The common electrode CM may be a common layer commonly disposed on the first through third light emitting layers. A capping layer may be formed on the common electrode CM.

In the top emission structure, the common electrode CM may include or be made of a transparent conductive material (TCO) capable of transmitting light, such as indium tin oxide (ITO) or indium zinc oxide (IZO), or a semi-transmissive conductive material such as magnesium (Mg), silver (Ag) or an alloy of Mg and Ag. In an embodiment where the common electrode CM includes or is made of a semi-transmissive conductive material, light output efficiency may be increased by a microcavity.

The encapsulation layer ENC may be formed on the light emitting element layer EMTL. The encapsulation layer ENC may include at least one inorganic layer TFE1 and TFE3 to prevent oxygen or moisture from penetrating into the light emitting element layer EMTL. In addition, the encapsulation layer ENC may include at least one organic layer to protect the light emitting element layer EMTL from foreign substances such as dust. In an embodiment, for example, the encapsulation layer ENC may include a first encapsulating inorganic layer TFE1, an encapsulating organic layer TFE2, and a second encapsulating inorganic layer TFE3.

The first encapsulating inorganic layer ITE1 may be disposed on the common electrode CM, the encapsulating organic layer TFE2 may be disposed on the first encapsulating inorganic layer TFE1, and the second encapsulating inorganic layer TFE3 may be disposed on the encapsulating organic layer TFE2. Each of the first encapsulating inorganic layer TFE1 and the second encapsulating inorganic layer TFE3 may be a multilayer in which inorganic layers, each layer including at least one selected from a silicon nitride layer, a silicon oxynitride layer, a silicon oxide layer, a titanium oxide layer, and an aluminum oxide layer, are alternately stacked. The encapsulating organic layer TFE2 may be an organic layer such as acryl resin, epoxy resin, phenolic resin, polyamide resin, or polyimide resin.

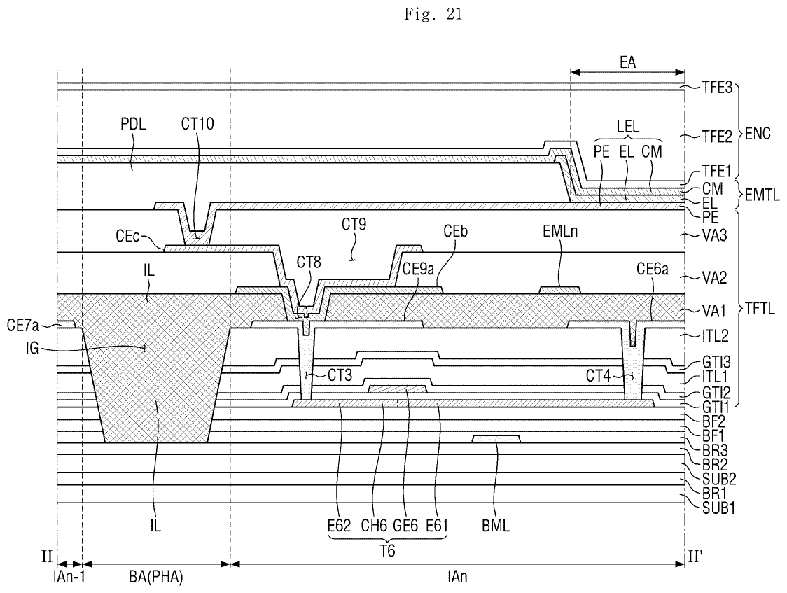

FIG. 21 is a cross-sectional view of the display device 10 according to an embodiment, taken along line II-II′ of FIG. 9B.

As illustrated in FIGS. 19 and 21, the isolation groove IG may have different depths in the pinhole area PHA and the non-pinhole area. In an embodiment, for example, the isolation groove IG may have a greater depth in the pinhole area PHA (see FIG. 21) than in the non-pinhole area (see FIG. 19). Here, the depth may be a size in the third direction (or the reverse of the third direction). In an embodiment, for example, as illustrated in FIG. 19, the isolation groove IG in the non-pinhole area may have a depth from the second interlayer insulating layer ITL2 to the first buffer layer BF1 under the second interlayer insulating layer ITL2. In addition, as illustrated in FIG. 21, the isolation groove IG in the pinhole area PHA may have a depth from the second interlayer insulating layer ITL2 to the third barrier layer BR3 under the second interlayer insulating layer ITL2. Since the isolation groove IG is formed to have a greater depth in the pinhole area PHA, light transmittance in the pinhole area PHA may be further improved. In an embodiment, for example, the first buffer layer BF1 may include a silicon oxide layer (e.g., SiO₂), and the second buffer layer BF2 may include a silicon nitride layer (e.g., SiNx) such that moisture permeation due to damage to the third barrier layer BR3 may be effectively prevented.

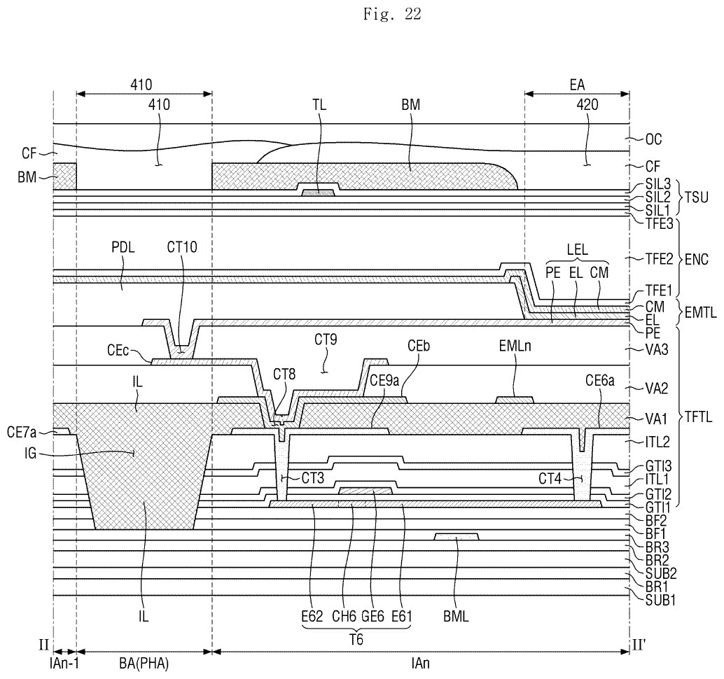

FIG. 22 is a cross-sectional view of the display device 10 according to an embodiment, taken along line II-II′ of FIG. 9B.

The embodiment of FIG. 22 is substantially the same as the embodiment of FIG. 21 except that a touch sensing layer TSU, a light blocking layer BM, color filters CF, and a planarization layer OC are further included. Therefore, any repetitive detailed description of the same or like elements as those described above will be omitted or simplified, and different features will be mainly described below.

In an embodiment, as illustrated in FIG. 22, the display device may include the touch sensing layer TSU, the light blocking layer BM, the color filters CF, and the planarization layer OC.

The touch sensing layer TSU may be disposed on the encapsulation layer ENC. The touch sensing layer TSU may include a first touch insulating layer SIL1, a second touch insulating layer SIL2, a touch electrode TL, and a third touch insulating layer SIL3.

The first touch insulating layer SIL1 may be disposed on the encapsulation layer ENC. The first touch insulating layer SIL1 may have insulating and optical functions. The first touch insulating layer SIL1 may include at least one inorganic layer. Alternatively, the first touch insulating layer SIL1 may be omitted.

The second touch insulating layer SIL2 may cover the first touch insulating layer SIL1. Although not illustrated in the drawing, a touch electrode TL of another layer may be further disposed on the first touch insulating layer SIL1, and the second touch insulating layer SIL2 may cover this touch electrode TL. The second touch insulating layer SIL2 may have insulating and optical functions. In an embodiment, for example, the second touch insulating layer SIL2 may be an inorganic layer including at least one selected from a silicon nitride layer, a silicon oxynitride layer, a silicon oxide layer, a titanium oxide layer, and an aluminum oxide layer.

Some of a plurality of touch electrodes TL may be disposed on the second touch insulating layer SIL2. The touch electrode TL may not overlap the emission area EA. The touch electrode TL may be a single layer of molybdenum (Mo), titanium (Ti), copper (Cu), aluminum (Al) or indium tin oxide (ITO) or may be a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide.

The third touch insulating layer SIL3 may cover the touch electrode TL and the second touch insulating layer SIL2. The third touch insulating layer SIL3 may have insulating and optical functions. The third touch insulating layer SIL3 may include or be made of at least one selected from materials of the second touch insulating layer SIL2.

The upper light blocking layer BM may be disposed on the third touch insulating layer SIL3 of the touch sensing layer TSU. The upper light blocking layer BM may cover a conductive line of the touch electrode TL but may be provided with a first opening 410 overlapping the pinhole area PHA and a second opening 420 overlapping the emission area EA. The first opening 410 may overlap the isolation groove IG of the pinhole area PHA. Light transmittance in the pinhole area PHA may be further improved by the first opening 410 of the light blocking layer BM. Here, the isolation groove IG of the pinhole area PHA overlapped by the first opening 410 of the upper light blocking layer BM may penetrate the second interlayer insulating layer ITL2, the third gate insulating layer GTI3, the first interlayer insulating layer ITL1, the second gate insulating layer GTI2, the first gate insulating layer GTI1, the second buffer layer BF2, and the first buffer layer BFT. In an embodiment, the isolation groove IG of the pinhole area PHA overlapped by the first opening 410 of the upper light blocking layer BM may be defined through the second interlayer insulating layer ITL2, the third gate insulating layer GTI3, the first interlayer insulating layer ITL1, the second gate insulating layer GTI2, the first gate insulating layer GTI, the second buffer layer BF2, the first buffer layer BF1, and the third barrier layer BR3.

The upper light blocking layer BM may include a light absorbing material. In an embodiment, for example, the upper light blocking layer BM may include an inorganic black pigment or an organic black pigment. The inorganic black pigment may be carbon black, and the organic black pigment may include at least one of lactam black, perylene black, and aniline black. However, the present disclosure is not limited thereto. The upper light blocking layer BM may prevent color mixing by preventing intrusion of visible light between first through third emission areas EA1 through EA3, thereby improving the color gamut of the display device 10.

The color filters CF may be disposed on the upper light blocking layer BM. Different color filters CF may be disposed to correspond to different emission areas, respectively.

The planarization layer OC may be disposed on the color filters CF to planarize upper ends of the color filters CF. The planarization layer OC may be a colorless light-transmitting layer that does not have a color of a visible light band. In an embodiment, for example, the planarization layer OC may include a colorless light-transmitting organic material such as acryl resin.

According to an embodiment, the color filters CF may be disposed on the upper light blocking layer BM to overlap each other. An overlap portion between the color filters CF disposed on the upper light blocking layer BM may completely cover the upper light blocking layer BM. Adjacent color filters CF may partially overlap each other on the upper light blocking layer BM. The overlap of the color filters CF may reduce reflection of external light by the upper light blocking layer BM.

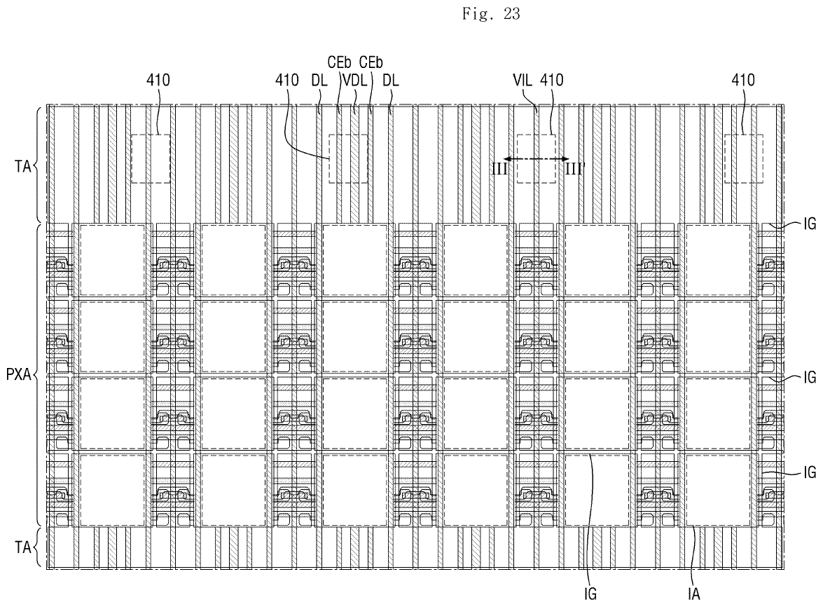

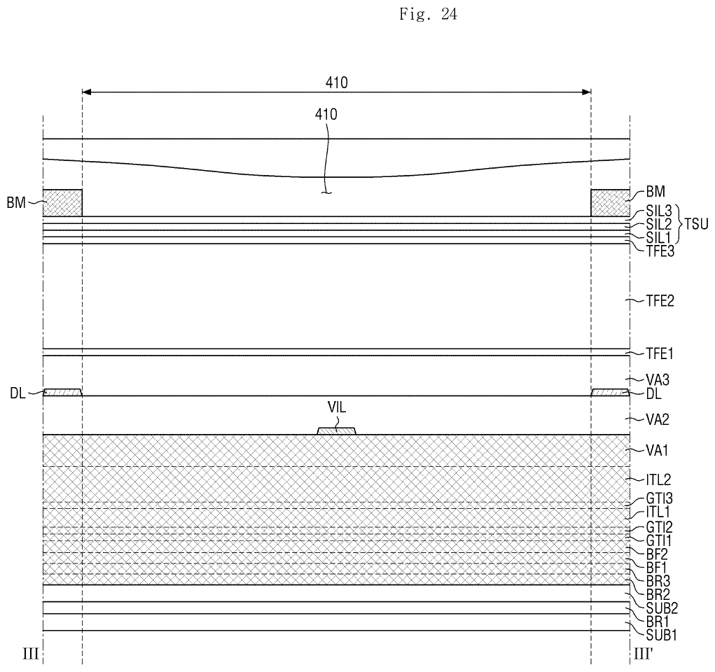

FIG. 23 is a plan view of the sub-display area SDA of the display device 10 according to an embodiment. FIG. 24 is a cross-sectional view of the display device 10 according to an embodiment, taken along line III-III′ of FIG. 23.

In an embodiment, as illustrated in FIG. 23, the sub-display area SDA of the display device 10 may include at least one pixel array area PXA and at least one transmissive area TA.

The pixel array area PXA may be, for example, an area in which pixels PX, the pixel illustrated in FIG. 5, are disposed. The pixel array area PXA may include a plurality of isolation areas IA, and patterns of the pixels PX, e.g., the pixels illustrated in FIG. 7, may be disposed in each isolation area IA.

The pixels PX may not be disposed in the transmissive area TA. The transmissive area TA may be disposed between pixel arrays PXA. The isolation groove IG may be defined in the entire transmissive area TA. The isolation groove IG of the transmissive area TA may be connected to the isolation groove IG of the pixel array area PXA.

The transmissive area TA may be disposed between adjacent pixel array areas PXA. Lines that connect, for example, the pixels PX of adjacent pixel array areas PXA may be disposed in the transmissive area TA. In an embodiment, for example, data lines DL, first driving voltage lines VDL, intermediate connection electrodes CEb, and initialization voltage lines VIL may be disposed in the transmissive area TA. Here, each of the initialization voltage lines VIL may be, for example, the first initialization voltage line VIL1 or the second initialization voltage line VIL2 described above.

In an embodiment, as illustrated in FIGS. 23 and 24, first openings 410 of the upper light blocking layer BM may be defined to correspond to the isolation groove IG of the transmissive area TA. In such an embodiment, the first openings 410 of the upper light blocking layer BM may overlap the isolation groove IG of the transmissive area TA. Accordingly, light transmittance in the transmissive area TA may be improved. Here, the depth of the isolation groove IG overlapping the transmissive area TA may be different from, for example, the depth of the isolation groove IG overlapping the pinhole areas PHA of the pixel array area PXA. In an embodiment, for example, the depth of the isolation groove IG overlapping the transmissive area TA may be greater than the depth of the isolation groove IG overlapping the pinhole areas PHA of the pixel array area PXA. In an embodiment, for example, the isolation groove IG in the transmissive area TA overlapping the first openings 410 of the upper light blocking layer BM may penetrate the second interlayer insulating layer ITL2, the third gate insulating layer GTI3, the first interlayer insulating layer ITL1, the second gate insulating layer GTI2, the first gate insulating layer GTI1, the second buffer layer BF2, the first buffer layer BFT, and the third barrier layer BR3. In an embodiment, the depth of the isolation groove IG overlapping the transmissive area TA may be equal to the depth of the isolation groove IG overlapping the pinhole areas PHA of the pixel array area PXA. In an embodiment, for example, the isolation groove IG in the transmissive area TA overlapping the first openings 410 of the upper light blocking layer BM may penetrate the second interlayer insulating layer ITL2, the third gate insulating layer GTI3, the first interlayer insulating layer ITL1, the second gate insulating layer GTI2, the first gate insulating layer GTI1, the second buffer layer BF2, and the first buffer layer BFT.

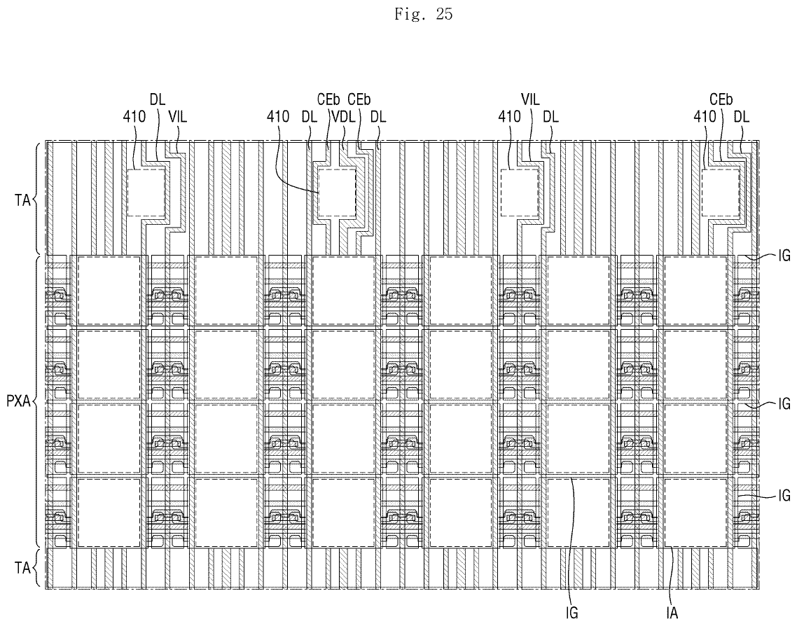

FIG. 25 is a plan view of a sub-display area of a display device according to an embodiment.

The embodiment of FIG. 25 is substantially the same as the embodiment of FIG. 23 except that lines in a transmissive area TA are bent to bypass first openings 410 of an upper light blocking layer BM. Therefore, any repetitive detailed description of the same or like elements as those described above will be omitted or simplified, and different features will be mainly described below.

In an embodiment, as illustrated in FIG. 25, at least one line (e.g., at least one of a data line DL, a first driving voltage line VDL, an intermediate connection electrode CEb, and an initialization voltage line VIL) of the transmissive area TA may be disposed not to overlap each first opening 410 of the upper light blocking layer BM. In such an embodiment, for example, the lines in the transmissive area TA may be bent to bypass the first openings 410 of the upper light blocking layer BM. Accordingly, light transmittance in the first openings 410 overlapping the transmission area TA may be improved.

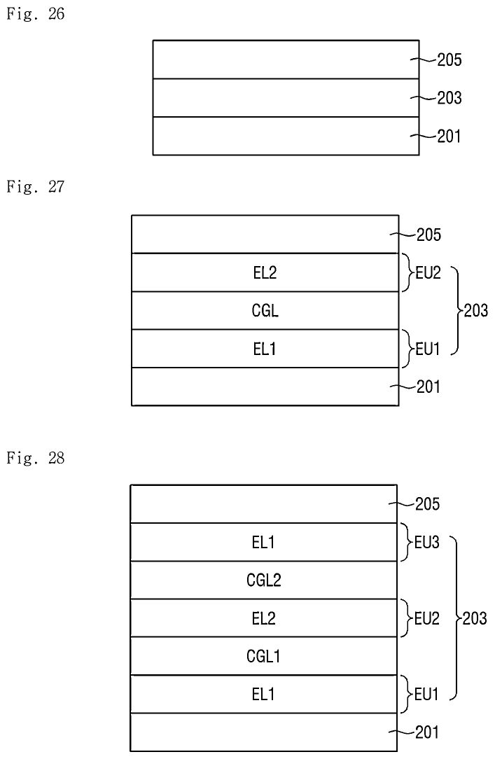

Hereinafter, other structures of the light emitting element (e.g., LEL of FIG. 19) will be described with reference to FIGS. 26 through 33.

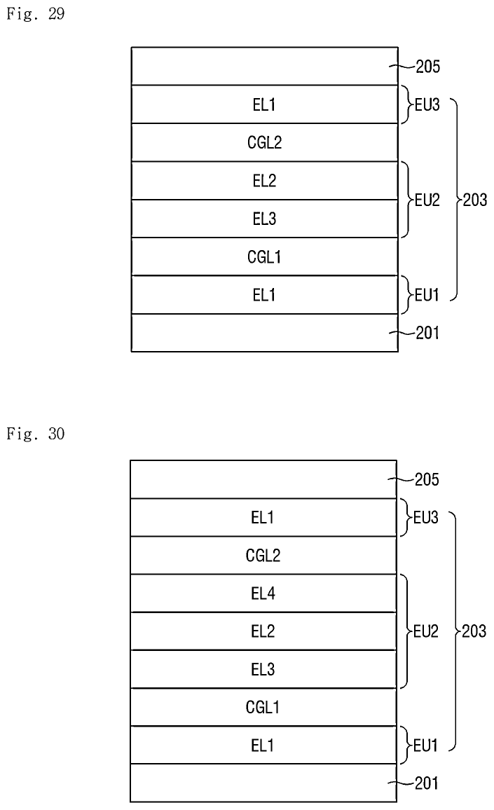

FIG. 26 is a cross-sectional view illustrating a structure of a display element according to an embodiment. FIGS. 27 through 30 are cross-sectional views illustrating structures of light emitting elements according to embodiments.

Referring to FIG. 26, a light emitting element (e.g., an organic light emitting diode) according to an embodiment may include a pixel electrode 201, a common electrode 205, and an intermediate layer 203 between the pixel electrode 201 and the common electrode 205.

The pixel electrode 201 may include a light-transmitting conductive oxide such as indium tin oxide (ITO), indium zinc oxide (IZO), zinc oxide (ZnO), indium oxide (In₂O₃), indium gallium oxide (IGO) or aluminum zinc oxide (AZO). The pixel electrode 201 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, for example, the pixel electrode 201 may have a three-layer structure of ITO/Ag/ITO.

The common electrode 205 may be disposed on the intermediate layer 203. The common electrode 205 may include a low-work function metal, alloy, electrically conductive compound, or any combination thereof. In an embodiment, for example, the common electrode 205 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The common electrode 205 may be a transmissive electrode, a transflective electrode, or a reflective electrode.

The intermediate layer 203 may include a polymer or low molecular weight organic material that emits light of a predetermined color. The intermediate layer 203 may further include a metal-containing compound such as an organometallic compound or an inorganic material such as quantum dots, in addition to various organic materials.

In an embodiment, the intermediate layer 203 may include one light emitting layer and a first functional layer and a second functional layer respectively disposed below and above the light emitting layer. The first functional layer may include, for example, a hole transport layer or may include a hole transport layer and a hole injection layer. The second functional layer is an element disposed on the light emitting layer and is optional. In an embodiment, for example, the intermediate layer 203 may or may not include the second functional layer. The second functional layer may include an electron transport layer and/or an electron injection layer.

In an embodiment, the intermediate layer 203 may include two or more light emitting units sequentially stacked between the pixel electrode 201 and the common electrode 205 and may include a charge generation layer disposed between the two light emitting units. In an embodiment where the intermediate layer 203 includes the light emitting units and the charge generation layer, the light emitting element (e.g., the organic light emitting diode) may be a tandem light emitting element. The light emitting element (e.g., the organic light emitting diode) having a stacked structure of a plurality of light emitting units may improve color purity and light emitting efficiency.

One light emitting unit may include a light emitting layer and a first functional layer and a second functional layer respectively disposed below and above the light emitting layer. The charge generation layer CGL may include a negative charge generation layer and a positive charge generation layer. The negative charge generation layer and the positive charge generation layer may further improve the light emitting efficiency of an organic light emitting diode which is a tandem light emitting element having a plurality of light emitting layers.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant.

In an embodiment, as illustrated in FIG. 27, a light emitting element (e.g., an organic light emitting diode) may include a first light emitting unit EU1 including a first light emitting layer EL1 and a second light emitting unit EU2 including a second light emitting layer EL2 stacked sequentially. A charge generation layer CGL may be disposed between the first light emitting unit EU1 and the second light emitting unit EU2. In an embodiment, for example, the light emitting element (e.g., the organic light emitting diode) may include a pixel electrode 201, the first light emitting layer EL1, the charge generation layer CGL, the second light emitting layer EL2, and a common electrode 205 stacked sequentially. A first functional layer and a second functional layer may be disposed below and above the first light emitting layer EL1, respectively. A first functional layer and a second functional layer may be included below and above the second light emitting layer EL2, respectively. The first light emitting layer EL1 may be a blue light emitting layer, and the second light emitting layer EL2 may be a yellow light emitting layer.

In an embodiment, as illustrated in FIG. 28, a light emitting element (e.g., an organic light emitting diode) may include a first light emitting unit EU1 and a third light emitting unit EU3 including a first light emitting layer EL1 and a second light emitting unit EU2 including a second light emitting layer EL2. A first charge generation layer CGL1 may be disposed between the first light emitting unit EU1 and the second light emitting unit EU2, and a second charge generation layer CGL2 may be disposed between the second light emitting unit EU2 and the third light emitting unit EU3. In an embodiment, for example, the light emitting element (e.g., the organic light emitting diode) may include a pixel electrode 201, the first light emitting layer EL1, the first charge generation layer CGL1, the second light emitting layer EL2, the second charge generation layer CGL2, the first light emitting layer EL1, and a common electrode 205 stacked sequentially. A first functional layer and a second functional layer may be disposed below and above the first light emitting layer EL1, respectively. A first functional layer and a second functional layer may be disposed below and above the second light emitting layer EL2, respectively. The first light emitting layer EL1 may be a blue light emitting layer, and the second light emitting layer EL2 may be a yellow light emitting layer.

In an embodiment, the second light emitting unit EU2 of the light emitting element (e.g., the organic light emitting diode) may further include a third light emitting layer EL3 and/or a fourth light emitting layer EL4 disposed directly below and/or above the second light emitting layer EL2 to directly contact the second light emitting layer EL2, in addition to the second light emitting layer EL2. Here, “directly contact” may mean that there is no other layer between the second light emitting layer EL2 and the third light emitting layer EL3 and/or between the second light emitting layer EL2 and the fourth light emitting layer EL4. The third light emitting layer EL3 may be a red light emitting layer, and the fourth light emitting layer EL4 may be a green light emitting layer.

In an embodiment, for example, as illustrated in FIG. 29, a light emitting element (e.g., an organic light emitting diode) may include a pixel electrode 201, a first light emitting layer EL1, a first charge generation layer CGL1, a third light emitting layer EL3, a second light emitting layer EL2, a second charge generation layer CGL2, a first light emitting layer EL1, and a common electrode 205 stacked sequentially. Alternatively, as illustrated in FIG. 30, alight emitting element (e.g., an organic light emitting diode) may include a pixel electrode 201, a first light emitting layer EL1, a first charge generation layer CGL1, a third light emitting layer EL3, a second light emitting layer EL2, a fourth light emitting layer EL4, a second charge generation layer CGL2, a first light emitting layer EL1, and a common electrode 205 stacked sequentially.

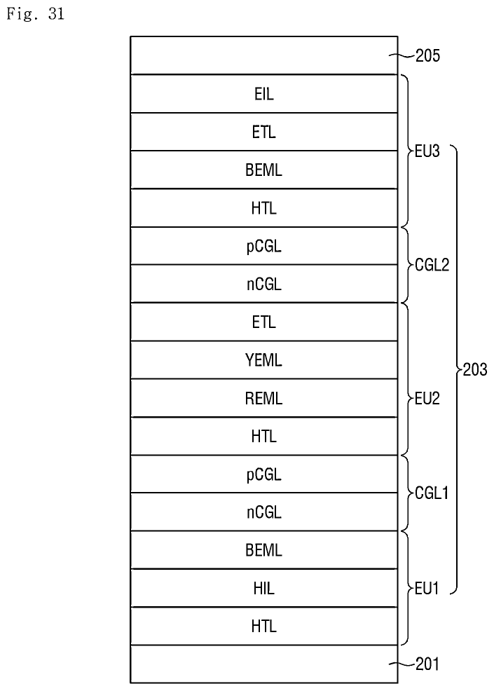

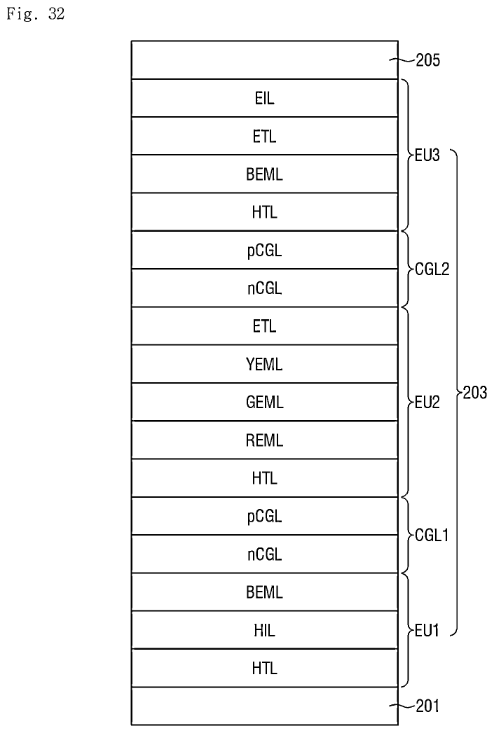

FIG. 31 is a cross-sectional view of an embodiment of the organic light emitting diode of FIG. 29. FIG. 32 is a cross-sectional view of an embodiment of the organic light emitting diode of FIG. 30.

Referring to FIG. 31, a light emitting element (e.g., an organic light emitting diode) may include a first light emitting unit EU1, a second light emitting unit EU2, and a third light emitting unit EU3 stacked sequentially. A first charge generation layer CGL1 may be disposed between the first light emitting unit EU1 and the second light emitting unit EU2, and a second charge generation layer CGL2 may be disposed between the second light emitting unit EU2 and the third light emitting unit EU3. Each of the first charge generation layer CGL1 and the second charge generation layer CGL2 may include a negative charge generation layer nCGL and a positive charge generation layer pCGL.

The first light emitting unit EU1 may include a blue light emitting layer BEML. The first light emitting unit EU1 may further include a hole injection layer HIL and a hole transport layer HTL between a pixel electrode 201 and the blue light emitting layer BEML. In an embodiment, a p-doped layer may be further included between the hole injection layer HIL and the hole transport layer HTL. The p-doped layer may be formed by doping the hole injection layer HIL with a p-type doping material. In an embodiment, at least one of a blue light auxiliary layer, an electron blocking layer, and a buffer layer may be further included between the blue light emitting layer BEML and the hole transport layer HTL. The blue light auxiliary layer may increase the light output efficiency of the blue light emitting layer BEML. The blue light auxiliary layer may increase the light output efficiency of the blue light emitting layer BEML by adjusting hole charge balance. The electron blocking layer may prevent injection of electrons into the hole transport layer HTL. The buffer layer may compensate for a resonance distance according to the wavelength of light emitted from the light emitting layer.

The second light emitting unit EU2 may include a yellow light emitting layer YEML and a red light emitting layer REML disposed under the yellow light emitting layer YEML to directly contact the yellow light emitting layer YEML. The second light emitting unit EU2 may further include a hole transport layer HTL between the positive charge generation layer pCGL of the first charge generation layer CGL1 and the red light emitting layer REML and may further include an electron transport layer ETL between the yellow light emitting layer YEML and the negative charge generation layer nCGL of the second charge generation layer CGL2.

The third light emitting unit EU3 may include a blue light emitting layer BEML. The third light emitting unit EU3 may further include a hole transport layer HTL between the positive charge generation layer pCGL of the second charge generation layer CGL2 and the blue light emitting layer BEML. The third light emitting unit EU3 may further include an electron transport layer ETL and an electron injection layer EIL between the blue light emitting layer BEML and a common electrode 205. The electron transport layer ETL may be a single layer or a multilayer. In an embodiment, at least one of a blue light auxiliary layer, an electron blocking layer, and a buffer layer may be further included between the blue light emitting layer BEML and the hole transport layer HTL. At least one of a hole blocking layer and a buffer layer may be further included between the blue light emitting layer BEML and the electron transport layer ETL. The hole blocking layer may prevent injection of holes into the electron transport layer ETL.

A light emitting element (e.g., an organic light emitting diode) illustrated in FIG. 32 is the same as the light emitting element (e.g., the organic light emitting diode) illustrated in FIG. 30 except for the stacked structure of a second light emitting unit EU2. Referring to FIG. 32, the second light emitting unit EU2 may include a yellow light emitting layer YEML, a red light emitting layer REML disposed below the yellow light emitting layer YEML to directly contact the yellow light emitting layer YEML, and a green light emitting layer GEML disposed above the yellow light emitting layer YEML to directly contact the yellow light emitting layer YEML. The second light emitting unit EU2 may further include a hole transport layer HTL between a positive charge generation layer pCGL of a first charge generation layer CGL1 and the red light emitting layer REML and may further include an electron transport layer ETL between the green light emitting layer GEML and a negative charge generation layer nCGL of a second charge generation layer CGL2.

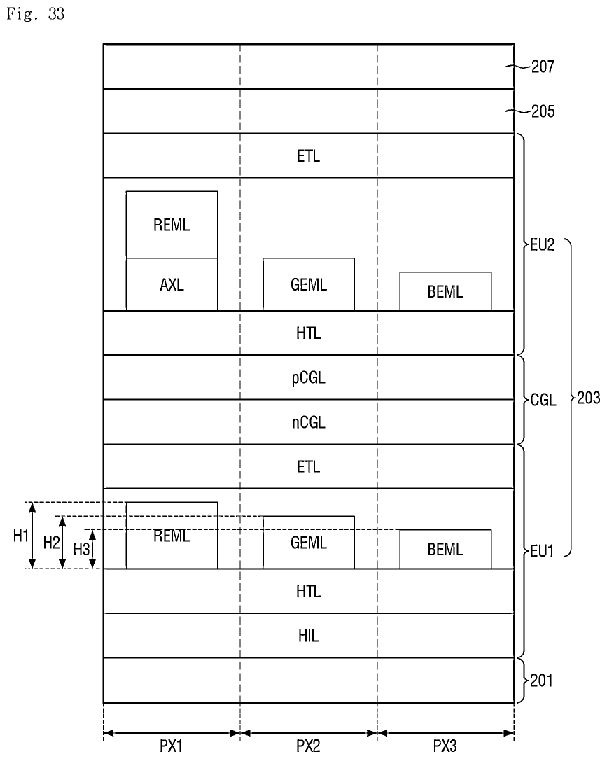

FIG. 33 is a cross-sectional view illustrating a pixel structure of a display device 10 according to an embodiment.

Referring to FIG. 33, a display panel 300 of the display device 10 may include a plurality of pixels (e.g., subpixels). The pixels may include a first pixel PX1, a second pixel PX2, and a third pixel PX3. Each of the first pixel PX1, the second pixel PX2, and the third pixel PX3 may include a pixel electrode 201, a common electrode 205, and an intermediate layer 203. In an embodiment, the first pixel PX1 may be a red pixel, the second pixel PX2 may be a green pixel, and the third pixel PX3 may be a blue pixel.

The pixel electrode 201 may be independently provided in each of the first pixel PX1, the second pixel PX2, and the third pixel PX3.

The intermediate layer 203 of each of the first pixel PX1, the second pixel PX2, and the third pixel PX3 may include a first light emitting unit EU1 and a second light emitting unit EU2 stacked sequentially and a charge generation layer CGL between the first light emitting unit EU1 and the second light emitting unit EU2. The charge generation layer CGL may include a negative charge generation layer nCGL and a positive charge generation layer pCGL. The charge generation layer CGL may be a common layer continuously formed in the first pixel PX1, the second pixel PX2, and the third pixel PX3.

The first light emitting unit EU1 of the first pixel PX1 may include a hole injection layer HIL, a hole transport layer HTL, a red light emitting layer REML, and an electron transport layer ETL sequentially stacked on the pixel electrode 201. The first light emitting unit EU1 of the second pixel PX2 may include the hole injection layer HIL, the hole transport layer HTL, a green light emitting layer GEML, and the electron transport layer ETL sequentially stacked on the pixel electrode 201. The first light emitting unit EU1 of the third pixel PX3 may include the hole injection layer HIL, the hole transport layer HTL, a blue light emitting layer BEML, and the electron transport layer ETL sequentially stacked on the pixel electrode 201. Each of the hole injection layer HIL, the hole transport layer HTL, and the electron transport layer ETL of the first light emitting units EU1 may be a common layer continuously formed in the first pixel PX1, the second pixel PX2, and the third pixel PX3.

The second light emitting unit EU2 of the first pixel PX1 may include a hole transport layer HTL, an auxiliary layer AXL, a red light emitting layer REML, and an electron transport layer ETL sequentially stacked on the charge generation layer CGL. The second light emitting unit EU2 of the second pixel PX2 may include the hole transport layer HTL, a green light emitting layer GEML, and the electron transport layer ETL sequentially stacked on the charge generation layer CGL. The second light emitting unit EU2 of the third pixel PX3 may include the hole transport layer HTL, a blue light emitting layer BEML, and the electron transport layer ETL sequentially stacked on the charge generation layer CGL. Each of the hole transport layer HTL and the electron transport layer ETL of the second light emitting units EU2 may be a common layer continuously formed in the first pixel PX1, the second pixel PX2, and the third pixel PX3. In an embodiment, at least one of a hole blocking layer and a buffer layer may be further included between the light emitting layer and the electron transport layer ETL in the second light emitting unit EU2 of each of the first pixel PX1, the second pixel PX2, and the third pixel PX3.

A thickness H1 of the red light emitting layer REML, a thickness H2 of the green light emitting layer GEML, and a thickness H3 of the blue light emitting layer BEML may be determined based on a resonance distance. The auxiliary layer AXL is a layer added to adjust the resonance distance and may include a resonance auxiliary material. In an embodiment, for example, the auxiliary layer AXL may include the same material as the hole transport layer HTL.

Although the auxiliary layer AXL is disposed only in the first pixel PX1 in FIG. 33, embodiments of the present disclosure are not limited thereto. In an embodiment, for example, the auxiliary layer AXL may also be disposed in at least one of the first pixel PX1, the second pixel PX2, and the third pixel PX3 to adjust the resonance distance of each of the first pixel PX1, the second pixel PX2, and the third pixel PX3.

The display panel 300 of the display device 10 may further include a capping layer 207 disposed outside the common electrode 205. The capping layer 207 may improve light emission efficiency through the principle of constructive interference. Accordingly, this may increase the light extraction efficiency of a light emitting element (e.g., an organic light emitting diode), thereby improving the light emission efficiency of the light emitting element (e.g., the organic light emitting diode).

A display device according to embodiments of the present disclosure may have improved transmittance. Therefore, the amount of light incident on an optical device of a sub-display area or the amount of light emitted from the optical device may increase, thereby improving the accuracy of the optical device.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate;
an insulating layer disposed on the substrate, wherein an isolation groove is defined in the insulating layer, and a plurality of isolation areas is defined by the isolation groove; and
a pixel circuit disposed in each of the isolation areas,
wherein at least two portions of the isolation groove have different widths from each other.

2. The display device of claim 1, wherein
a portion of the isolation groove overlaps a pinhole area defined by patterns of the pixel circuit, and
the portion of the isolation groove overlapping the pinhole area has a greater width than a portion of the isolation groove not overlapping the pinhole area.

3. The display device of claim 2, wherein the portion of the isolation groove overlapping the pinhole area has a greater depth than the portion of the isolation groove not overlapping the pinhole area.

4. The display device of claim 2, further comprising:
an upper light blocking layer disposed on the insulating layer, wherein having an opening overlapping the pinhole area is defined through the upper light blocking layer.

5. The display device of claim 2, wherein the isolation groove is further defined in a transmissive area in which a pixel comprising the pixel circuit is not disposed.

6. The display device of claim 5, further comprising:
an upper light blocking layer disposed on the insulating layer, wherein an opening overlapping the transmissive area is defined through the upper light blocking layer.

7. The display device of claim 6, further comprising:
a line disposed in the transmissive area and connecting pixels disposed at opposing sides of the transmissive area to each other.

8. The display device of claim 7, wherein the line comprise a data line, an intermediate connection electrode, a first initialization voltage line, and a second initialization voltage line.

9. The display device of claim 7, wherein the line is disposed in the transmissive area not to overlap the opening of the upper light blocking layer.

10. The display device of claim 9, wherein the line is bent in the transmissive area to bypass the opening of the upper light blocking layer.

11. The display device of claim 5, wherein the portion of the isolation groove overlapping the pinhole area has a different depth from a portion of the isolation groove overlapping the transmissive area.

12. The display device of claim 11, wherein the portion of the isolation groove overlapping the transmissive area has a greater depth than the portion of the isolation groove overlapping the pinhole area.

13. The display device of claim 2, wherein the pixel circuit comprises a first transistor, a second transistor, a third transistor, a fourth transistor, a fifth transistor, a sixth transistor, a seventh transistor, and a capacitor.

14. The display device of claim 13, wherein in a plan view, the pinhole area is defined by an area surrounded by an intermediate connection electrode connecting the sixth transistor and the seventh transistor to each other, a pattern comprising a gate electrode of the fifth transistor, a lower light blocking layer overlapping the first transistor, and an active layer connected to the seventh transistor.

15. The display device of claim 13, wherein in a plan view, the pinhole area is defined by an area surrounded by a power connection electrode connected to the fifth transistor, a lower light blocking layer overlapping the first transistor, and a first initialization voltage line connected to the seventh transistor.

16. The display device of claim 13, wherein
the first transistor comprises a gate electrode connected to a third node, a first electrode connected to a first node and a second electrode connected to a second node,
the second transistor comprises a gate electrode connected to a first gate line, a first electrode connected to a data line and a second electrode connected to the first node,
the third transistor comprises a gate electrode connected to a second gate line, a first electrode connected to the third node and a second electrode connected to the second node,
the fourth transistor comprises a gate electrode connected to a third gate line, a first electrode connected to the third node and a second electrode connected to a first initialization voltage line,
the fifth transistor comprises the gate electrode connected to an emission control line, a first electrode connected to a first driving voltage line and a second electrode connected to the first node,
the sixth transistor comprises a gate electrode connected to the emission control line, a first electrode connected to the second node and a second electrode connected to a pixel electrode,
the seventh transistor comprises a gate electrode connected to a fourth gate line, a first electrode connected to the pixel electrode and a second electrode connected to a second initialization voltage line, and
the capacitor comprises a first electrode connected to the first driving voltage line and a second electrode connected to the third node.

17. A display device comprising:
a substrate;
an insulating layer disposed on the substrate, wherein an isolation groove is defined in the insulating layer, and a plurality of isolation areas is defined by the isolation groove; and
a pixel circuit disposed in each of the isolation areas,
wherein at least two portions of the isolation groove have different widths or depths from each other.

18. The display device of claim 17, wherein
a portion of the isolation groove overlaps a pinhole area defined by patterns of the pixel circuit, and
the portion of the isolation groove overlapping the pinhole area has a greater width or depth than a portion of the isolation groove not overlapping the pinhole area.

19. The display device of claim 18, further comprising:
an upper light blocking layer disposed on the insulating layer, wherein an opening overlapping the pinhole area is defined through the upper light blocking layer.

20. The display device of claim 18, wherein the isolation groove is further defined in a transmissive area in which a pixel comprising the pixel circuit is not disposed.

21. The display device of claim 20, further comprising:
an upper light blocking layer disposed on the insulating layer, wherein an opening overlapping the transmissive area is defined through the upper light blocking layer.
